(19) United States
(12) Patent Application Publication
(10) Pub. No.: US 2026/0072535 A1
(43) Pub. Date: Mar. 12, 2026

(54) DISPLAY PANEL AND DISPLAY DEVICE

(71) Applicants: KunShan Go-Visionox Opto-Electronics Co., Ltd., Kunshan (CN); Hefei Visionox Technology Co., Ltd., Hefei (CN)

(72) Inventors: Lihua WANG, Kunshan (CN); Junhui LOU, Kunshan (CN); Haifeng LU, Hefei (CN); Rubo XING, Kunshan (CN)

(73) Assignees: KunShan Go-Visionox Opto-Electronics Co., Ltd., Kunshan (CN); Hefei Visionox Technology Co., Ltd., Hefei (CN)

(21) Appl. No.: 19/394,795

(22) Filed: Nov. 19, 2025

(30) Foreign Application Priority Data
Nov. 29, 2024 (CN) 202411755121.7

(51) Int. Cl. G06F 3/041; H10K 59/40; H10K 59/88

(52) U.S. Cl. CPC G06F 3/0412; H10K 59/40; H10K 59/88

(57) ABSTRACT

The present application relates to a display panel and a display device. The display panel includes: a substrate, a light-emitting functional layer, a plurality of touch electrodes, and a plurality of touch leads, where the light-emitting functional layer includes a light-emitting layer and a first electrode layer; each of the touch electrodes includes a plurality of touch electrode portions; there is a first spacing between two of the touch electrodes disposed adjacent to each other in a first direction; at least part of the touch leads extend in a second direction, and are located in the first spacings; and the touch leads are connected to corresponding ends of the plurality of touch electrode portions of the corresponding touch electrodes.

### CROSS-REFERENCE TO RELATED APPLICATIONS

The present application claims priority to Chinese Patent Application No. 202411755121.7, filed on Nov. 29, 2024 and entitled “DISPLAY PANEL AND DISPLAY DEVICE”, the disclosure of which is incorporated herein by reference in its entirety.

### FIELD

The present application relates to the field of display, and in particular to a display panel and a display device.

### BACKGROUND

Organic light emitting diodes (OLED) display technology is considered as the next generation of the most promising new flat panel display technology. Compared to liquid crystal display technology, OLED display technology has advantages such as low energy consumption, low cost, self-luminescence, a wide angle of view and fast response. However, a touch performance of a display panel formed by the above display technology needs to be improved.

### SUMMARY

In view of this, it is necessary to provide a display panel and display device that can improve the touch performance of the display panel.

In an embodiment of the present application provides a display panel, including:
a substrate;
a light-emitting functional layer disposed on a side of the substrate, the light-emitting functional layer comprising a light-emitting layer and a first electrode layer disposed in sequence in a direction away from the substrate, and the light-emitting layer comprising a plurality of light-emitting units;
a plurality of touch electrodes spaced apart on a side of the substrate; where in the same touch electrode, the touch electrode includes a plurality of touch electrode portions arranged at intervals in a second direction; and there is a first spacing between two of the touch electrodes disposed adjacent to each other in a first direction; and
a plurality of touch leads, at least part of the touch leads being disposed in a same layer as the touch electrodes, and at least part of the touch leads extending in the second direction and located in the first spacings; and the plurality of touch leads being disposed corresponding to the plurality of touch electrodes, and the touch leads being connected to corresponding ends of the plurality of touch electrode portions of the corresponding touch electrodes.

According to the display panel according to the embodiments of the present application, the plurality of touch electrode portions of the same touch electrode are arranged at intervals in the second direction, and the touch leads are connected to the corresponding ends of the plurality of touch electrode portions of the corresponding touch electrodes, and it is possible to avoid a reduced touch accuracy caused by arranging the plurality of touch electrode portions of the same touch electrode at intervals in the first direction and connecting the touch leads to the middle portions of the plurality of touch electrode portions of the corresponding touch electrodes in the second direction, to increase the touch accuracy of the display panel and improve the touch performance of the display panel.

In one of the embodiments, there is a second spacing between adjacent two of the touch electrode portions.

In one embodiment, orthographic projections of the touch electrodes on the substrate correspond to spacings between the orthographic projections of adjacent light-emitting units on the substrate.

In one embodiment, the first electrode layer includes a plurality of first electrode portions, the first electrode portions being disposed corresponding to the touch electrodes, and the first electrode portions each including first sub-electrode portions and a plurality of second sub-electrode portions. In the first electrode portions and the corresponding touch electrodes, the second sub-electrode portions are disposed corresponding to the second spacings between the touch electrodes, orthographic projections of the second sub-electrode portions on the substrate overlap with orthographic projections of the corresponding second spacings on the substrate, and the first sub-electrode portions are connected to ends of the plurality of second sub-electrode portions away from the corresponding touch leads.

In one embodiment, the first sub-electrode portions of at least part of adjacent first electrode portions of the first electrode portions in the second direction are connected.

In one embodiment, a minimum distance between at least part of the adjacent touch electrodes in the second direction is equal to a minimum distance in the second direction between adjacent two of the touch electrode portions of the same touch electrode.

In one embodiment, the first direction is perpendicular to the second direction.

In one of the embodiments, each of the touch leads includes a first sub-touch lead, the first sub-touch lead being in contact with a corresponding one of the touch electrodes.

In one embodiment, orthographic projections of the plurality of touch leads on the substrate do not overlap with each other.

In one embodiment, the first sub-touch leads extend in the second direction.

In one embodiment, the touch lead includes a second sub-touch lead, the second sub-touch lead extending in a direction away from the corresponding touch electrode in the second direction and being disposed at a distance from the first sub-touch lead.

In one embodiment, the touch lead includes a third sub-touch lead located between the first sub-touch lead and the third sub-touch lead.

In one embodiment, the third sub-touch lead extends in the first direction. Alternatively, the third sub-touch lead includes a first sub-lead and a second sub-lead arranged alternately and connected end-to-end, the first sub-lead extending in the first direction, and the second sub-lead extending in the second direction.

In one embodiment, in adjacent two of the touch electrodes in the second direction, the two touch electrodes are disposed opposite each other in the second direction. Alternatively, in the adjacent two of the touch electrodes in the second direction, the two touch electrodes are disposed partially opposite each other and partially misaligned with each other in the second direction.

In one of the embodiments, there is a second spacing between adjacent two of the touch electrode portions. The second spacing includes a plurality of first openings and first gaps, the plurality of first openings being arranged at intervals in the first direction, and adjacent two of the first gaps communicating with each other through the first gap.

The first openings are disposed corresponding to the light-emitting units, orthographic projections of the light-emitting units on the substrate overlapping with orthographic projections of the corresponding first openings on the substrate.

In one of the embodiments, at least part of the first openings are disposed corresponding to at least two of the light-emitting units arranged in the second direction.

In the embodiments of the present application provide a display panel, including:
a substrate;
a light-emitting functional layer disposed on a side of the substrate, the light-emitting functional layer comprising a light-emitting layer and a first electrode layer disposed in sequence in a direction away from the substrate, and the light-emitting layer comprising a plurality of light-emitting units;
a plurality of touch electrodes spaced apart on a side of the substrate; where in the same touch electrode, the touch electrode includes a plurality of touch electrode portions arranged at intervals in a second direction, there is a first spacing between two of the touch electrodes disposed adjacent to each other in a first direction, and there is a second spacing between adjacent two of the touch electrode portions; and
a plurality of touch leads, at least part of the touch leads being disposed in a same layer as the touch electrodes, and at least part of the touch leads extending in the second direction and located in the first spacings; and the plurality of touch leads being disposed corresponding to the plurality of touch electrodes, and the touch leads being connected to corresponding ends of the plurality of touch electrode portions of the corresponding touch electrodes;
where the first electrode layer includes a plurality of first electrode portions arranged at intervals, the first electrode portions being disposed corresponding to the touch electrodes, and the first electrode portions each comprising first sub-electrode portions and a plurality of second sub-electrode portions; and in the first electrode portions and the corresponding touch electrodes, the second sub-electrode portions are disposed corresponding to the second spacings between the touch electrodes, orthographic projections of the second sub-electrode portions on the substrate overlap with orthographic projections of the corresponding second spacings on the substrate, and the first sub-electrode portions are connected to ends of the plurality of second sub-electrode portions away from the corresponding touch leads.

In the embodiments of the present application provide a display device, including the display panel of the embodiments described above.

The display device according to the embodiments of the present application includes a display panel, where the plurality of touch electrode portions of the same touch electrode are arranged at intervals in the second direction, and the touch leads are connected to the corresponding ends of the plurality of touch electrode portions of the corresponding touch electrodes, and it is possible to avoid a reduced touch accuracy caused by arranging the plurality of touch electrode portions of the same touch electrode at intervals in the first direction and connecting the touch leads to the middle portions of the plurality of touch electrode portions of the corresponding touch electrodes in the second direction, to increase the touch accuracy of the display panel and improve the touch performance of the display panel.

### BRIEF DESCRIPTION OF THE DRAWINGS

To describe the embodiments of the present application more clearly, the following briefly describes the accompanying drawings required for describing the embodiments or the exemplary embodiments. Apparently, the accompanying drawings in the following description show merely some embodiments of the present application.

FIG. 1 is a cross-sectional view of a display panel according to an embodiment of the present application.

FIG. 2 is a top view of a display panel according to an embodiment of the present application.

FIG. 3 is a top view of a first electrode layer, touch electrodes, dummy electrodes and touch leads according to an embodiment of the present application.

FIG. 4 is another top view of the first electrode layer, the touch electrodes, the dummy electrodes and the touch leads according to an embodiment of the present application.

FIG. 5 is yet another top view of the first electrode layer, the touch electrodes, the dummy electrodes and the touch leads according to an embodiment of the present application.

FIG. 6 is a top view of first electrode portions, the touch electrodes and the touch leads according to an embodiment of the present application.

FIG. 7 is a top view of first electrode portions, the touch electrodes and the touch leads according to an embodiment of the present application.

FIG. 8a is a partial enlarged top view of the first electrode layer, the touch electrodes, first dummy electrodes and touch traces according to an embodiment of the present application.

FIG. 8b is a partial enlarged top view of the first electrode portions and the touch electrodes according to an embodiment of the present application.

FIG. 9 is a partial enlarged top view of the first electrode portions and a first isolation structure according to an embodiment of the present application.

FIG. 10 is another partial enlarged top view of the touch electrodes and the first electrode portions according to an embodiment of the present application.

FIG. 11 is yet another partial enlarged top view of the touch electrodes and the first electrode portions according to an embodiment of the present application.

FIG. 12 is still yet another partial enlarged top view of the touch electrodes and the first electrode portions according to an embodiment of the present application.

FIG. 13 is a partial enlarged top view of second electrode portions and the first dummy electrodes according to an embodiment of the present application.

FIG. 14 is a partial enlarged top view of the second electrode portions and a second isolation structure according to an embodiment of the present application.

FIG. 15 is another partial enlarged top view of the second electrode portions and the first dummy electrodes according to an embodiment of the present application.

FIG. 16 is a partial enlarged top view of third electrode portions and second dummy electrodes according to an embodiment of the present application.

FIG. 17 is a partial enlarged top view of the third electrode portions and a third isolation structure according to an embodiment of the present application.

### LIST OF REFERENCE SIGNS

100. Display panel; 100a. Active area; 100b. Non-active area; 101. First encapsulation layer; 102. Second encapsulation layer; 103. Third encapsulation layer; 104. Substrate; 105. Touch chip; 106. Flexible circuit board; 107. Conductor wire; 110. First dummy electrode; 110a. First dummy electrode portion; 111. First sub-portion; 1112. Second extension section; 1122. Second connecting section; 120. Second dummy electrode; 120a. Second dummy electrode portion; 122. Second sub-portion; 1223. Third extension section; 1233. Third connecting section; 130. Light-emitting functional layer; 131. First electrode layer; 1311. First electrode portion; 1311a. First sub-electrode portion; 1311b. Second sub-electrode portion; 1312. Second electrode portion; 1312c. Third sub-electrode portion; 1312d. Fourth sub-electrode portion; 1313. Third electrode portion; 1313e. Fifth sub-electrode portion; 1313f. Sixth sub-electrode portion; 132. Second electrode layer; 133. Light-emitting layer; 1331. Light-emitting unit; 140a. Row of touch electrodes; 140b. Column of touch electrodes; 140c. Touch electrode group; 140d. Row of touch electrode groups; 140. Touch electrode; 141. Touch electrode portion; 141a. First touch electrode portion; 141b. Second touch electrode portion; 1411. First extension section; 1411a. First extension segment; 1411b. Second extension segment; 1411c. Third extension segment; 1421. First connecting section; 150. Touch lead; 151. First sub-touch lead; 152. Second sub-touch lead; 153. Third sub-touch lead; 1531. First sub-lead; 1532. Second sub-lead; 161. First spacing; 162. Second spacing; 163. Third spacing; 164. Fourth spacing; 165. Fifth spacing; 166. Sixth spacing; 167. Seventh spacing; 171. First opening; 172. Second opening; 173. Third opening; 174. Fourth opening; 175. Fifth opening; 176. Sixth opening; 181. First gap; 182. Second gap; 183. Third gap; 184. Fourth gap; 185. Fifth gap; 186. Sixth gap; 1871. First auxiliary gap; 1872. Second auxiliary gap; 1873. Third auxiliary gap; 1874. Fourth auxiliary gap; 191. First isolation structure; 1911. First isolating portion; 1912. Second isolating portion; 192. Second isolation structure; 193. Third isolation structure; 210. Pixel defining layer; 211. Pixel opening; 230. Third dummy electrode.

### DETAILED DESCRIPTION OF THE EMBODIMENTS

For ease of understanding the present application, the present application will be described more comprehensively below with reference to relevant accompanying drawings. Preferred embodiments of the present application are given in the accompanying drawings. However, the present application may be implemented in many different forms and is not limited to the embodiments described herein. Rather, these embodiments are provided for a more thorough and comprehensive understanding of the content disclosed in the present application.

It should be understood that although terms such as “first”, “second”, etc. may be used herein to describe various elements, these terms do not indicate any order, quantity, or importance, but are merely used to distinguish different components. These terms are merely used to distinguish one element from another. For example, without departing from the scope of the present application, a first element may be referred to as a second element, and similarly, a second element may be referred to as a first element. The term such as “comprise” or “include” means that the elements or parts preceding the term encompass the elements or part and equivalents thereof after the term, and do not exclude other elements or parts.

Unless otherwise defined, all technical and scientific terms used herein shall have the same meanings as commonly understood in the art to which this application relates. The terms used herein in the description of the present application are merely for the purpose of describing specific embodiments, and are not intended to limit the present application. The term “and/or” used herein includes any and all combinations of one or more of the associated listed items.

Organic light emitting diodes (OLED) display technology is considered as the next generation of the most promising new flat panel display technology. Compared to liquid crystal display technology, OLED display technology has advantages such as low energy consumption, low cost, self-luminescence, a wide angle of view and fast response.

During implementing the present application, the inventors have found that there are the following problems in the related art. The display panel may include a substrate, and a cathode layer, a plurality of touch electrodes and a plurality of touch leads which are disposed on the substrate, where the touch electrodes and the touch leads are disposed in a one-to-one correspondence, each touch electrode includes a plurality of touch electrode portions, and the plurality of touch electrode portions are arranged at intervals in a column direction, with a gap between adjacent two of the touch electrode portions. In the touch electrodes and the touch leads corresponding thereto, each touch lead includes a contact portion in contact with the touch electrode portion, the contact portions extend in the column direction, the plurality of touch electrode portions of the touch electrodes are connected to the contact portions in the middle in a row direction, and the touch lead separates the same gap into a first gap and a second gap. The cathode layer includes a plurality of cathode portions. The plurality of cathode portions are disposed corresponding to the plurality of touch electrodes. Each of the cathode portions includes a first connecting portion, a second connecting portion, a plurality of first sub-electrode portions, and a plurality of second sub-electrode portions. The first sub-electrode portions and the second sub-electrode portions are located on two sides of the contact portions, respectively. The first sub-electrode portions are disposed corresponding to the first gaps. Orthographic projections of the first sub-electrode portions on the substrate overlap with orthographic projections of the first gaps on the substrate. The first sub-electrode portions are arranged corresponding to the second gaps. Orthographic projections of the second sub-electrode portions on the substrate overlap with Orthographic projections of the second gaps on the substrate. The first connecting portion is connected to each of ends of the first sub-electrode portions away from the contact portions to provide a cathode potential to the first sub-electrode portions through the first connecting portion. The second connecting portion is connected to each of ends of the second sub-electrode portions away from the contact portion to provide a cathode potential to the second sub-electrode portions through the second connecting portion. Orthographic projections of the first connecting portion and the second connecting portion on the substrate are located on two sides of orthographic projections of the touch electrodes on the substrate in the row direction, and the orthographic projections of the first connecting portion and the second connecting portion on the substrate are provided between the orthographic projections of adjacent two of the touch electrodes in the row direction on the substrate.

However, the first connecting portion provides a cathode potential to corresponding first sub-electrode portions, and the second connecting portion provides a cathode potential to corresponding second sub-electrode portions. Both the number of first sub-electrode portions and the number of the second sub-electrode portions are high and the total current on the first connecting portion and the second connecting portion is large. In order to reduce a voltage drop across the first connecting portion and the second connecting portion, the first connecting portion and the second connecting portion need to be dimensioned to be large in the row direction, resulting in a large distance in the row direction between adjacent two touch electrode portions. This results in a large area of a touch dead zone and a reduced touch accuracy of a display panel, affecting the touch performance of the display panel.

In view of at least one of the above problems, the embodiments of the present application provide a display panel and display device, which can increase the touch accuracy of the display panel and improve the touch performance of the display panel.

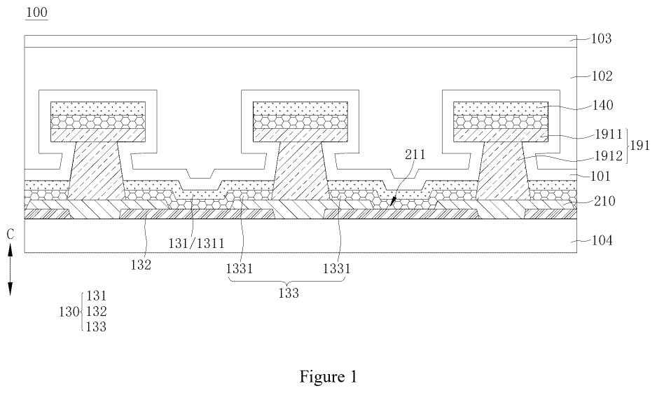

The display device according to the embodiments of the present application is illustrated below with reference to FIGS. 1 to 17.

An embodiment of the present application provides a display device, including a display panel 100. The display device may be an electronic paper, a mobile phone, a tablet, a TV set, a display, a notebook computer, a digital photo frame, a smart bracelet, a smart watch, a super personal computer, a navigator, a wireless device, a personal digital assistant (PDA), a handheld or portable computer, a GPS receiver/navigator, a camera, an MP4 video player, a video camera, a game console, a clock, a calculator, a television monitor, a computer monitor, a vehicle display (e.g., an odometer display, etc.), a cockpit controller and/or display, a camera view display (e.g., a display for a rearview camera in a vehicle), an electronic billboard or signboard, a mobile or fixed terminal such as a projector.

By way of example, the display panel 100 may be an organic light-emitting diode (OLED) display panel, a micro organic light-emitting diode (“micro OLED”) display panel, a light-emitting diode (LED) display panel, a quantum dot light emitting diode (QLED) display panel, a mini light emitting diode (MiniLED) display panel, a micro light emitting diode (micro LED) display panel, or a liquid crystal display (LCD) display panel, etc. The embodiments of the present application are described with an OLED display panel as an example.

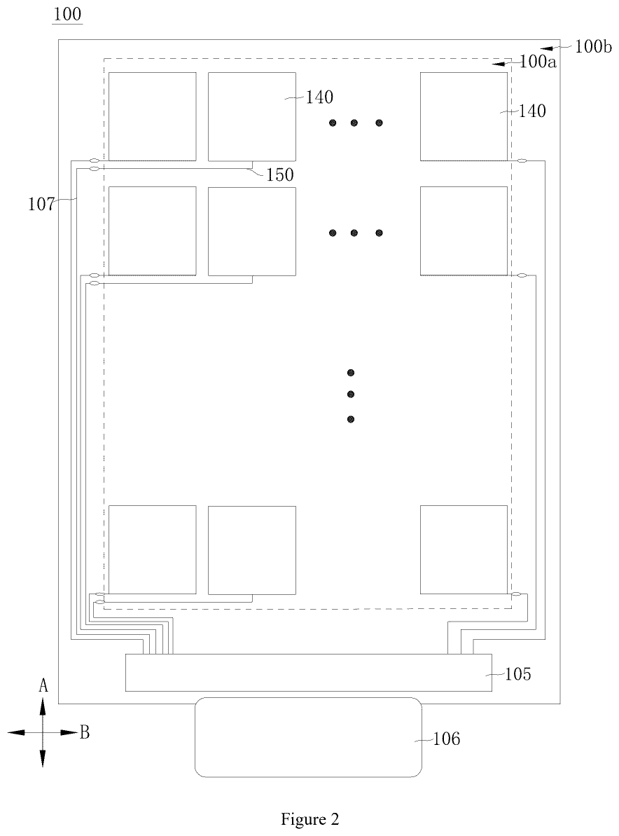

Referring to FIGS. 1 and 2, the display panel 100 may have a first direction A, a second direction B, and a third direction C. The first direction A, the second direction B and the third direction C are all different. The first direction A and the second direction B may be any two different directions parallel to the display panel 100, and the third direction C may be any direction intersecting a plane parallel to the display panel 100. For example, the first direction A, the second direction B and the third direction C may be perpendicular to each other. By way of example, the first direction A may be a length direction of the display panel 100, the second direction B may be a width direction of the display panel 100, and the third direction C may be a thickness direction of the display panel 100. The length, width, thickness, etc. in the embodiments of the present application are merely for ease of description and do not imply any limitation on dimensions. For example, the width may be greater than, equal to, or less than the length. The display panel 100 may have an orientation that is identical to an orientation of each of film layers such as a substrate 104.

The display panel 100 according to the embodiments of the present application is described below.

Referring to FIG. 1, the embodiments of the present application provides a display panel 100. The display panel 100 may include a substrate 104. The substrate 104 may provide support for other film layers that are subsequently provided.

Referring to FIG. 1, the display panel 100 may include a light-emitting functional layer 130. The light-emitting functional layer 130 is disposed on one side of the substrate 104, and the light-emitting functional layer 130 includes a second electrode layer 132, a light-emitting layer 133 and a first electrode layer 131 sequentially disposed in a direction away from the substrate 104.

By way of example, the light-emitting layer 133 includes a plurality of light-emitting units 1331. The plurality of light-emitting units 1331 may be arranged in an array, and the plurality of light-emitting units 1331 are arranged at intervals.

By way of example, the second electrode layer 132 may include a plurality of second electrodes that may be arranged at intervals.

By way of example, one of the first electrode layer 131 and the second electrode layer 132 may be an anode, and the other of the first electrode layer 131 and the second electrode layer 132 may be a cathode. The embodiments of the present application are described with respect to an example in which the second electrode layer 132 is an anode and the first electrode layer 131 is a cathode.

By way of example, the first electrode layer 131 may be electrically connected to a first power wire, where the first power wire provides a first potential. The second electrode layer 132 may be electrically connected to a pixel driving circuit, where the pixel driving circuit may be electrically connected to a second power wire, and the second power wire provides a second potential. One of the first power wire and the second power wire is configured to transmit a high voltage and the other thereof is configured to transmit a low voltage. For example, the first power wire is configured to transmit a low voltage (i.e., the first potential) and the second power wire is configured to transmit a high voltage (i.e., the second potential).

By way of example, the light-emitting functional layer 130 may further include one or more of a hole injection layer (HIL), a hole transport layer (HTL), an electron injection layer (EIL), an electron transport layer (ETL), a hole block layer (HBL) and an electron block layer (EBL).

By way of example, the plurality of light-emitting units 1331 may include red light-emitting units, green light-emitting units, and blue light-emitting units. In other examples, the plurality of light-emitting units 1331 may further include white light-emitting units.

Referring to FIGS. 1 and 2, the display panel 100 may include a plurality of touch electrodes 140 and a plurality of touch leads 150, where the plurality of touch electrodes 140 are spaced apart on one side of the substrate 104, and the touch electrodes 140 may implement a touch function of the display panel 100. The plurality of touch leads 150 are disposed corresponding to the plurality of touch electrodes 140, and the touch leads 150 are configured to connect corresponding touch electrodes 140 and a touch chip 105.

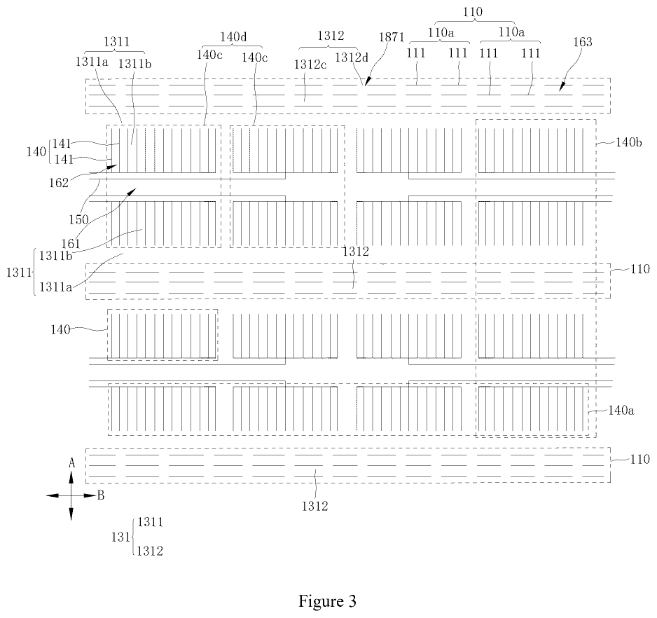

Referring to FIG. 3, for the same touch electrode 140, the touch electrode 140 includes a plurality of touch electrode portions 141 arranged at intervals in the second direction B. There is a second spacing 162 between adjacent two of the touch electrode portions 141. There is a first spacing 161 between two touch electrodes 140 disposed adjacent to each other in the first direction A. At least part of the touch leads 150 extend in the second direction B, and at least part of the touch leads 150 may be located in the first spacing 161. The touch leads 150 are connected to corresponding ends of the plurality of touch electrode portions 141 of corresponding touch electrodes 140. In other words, the touch leads 150 are connected to the same end portions of the plurality of touch electrode portions 141 of the corresponding touch electrodes 140 in the first direction A. As such, the plurality of touch electrode portions 141 of the same touch electrode 140 are arranged at intervals in the second direction B, and the touch leads 150 are connected to the corresponding ends of the plurality of touch electrode portions 141 of the corresponding touch electrodes 140, and it is possible to avoid a reduced touch accuracy caused by arranging the plurality of touch electrode portions 141 of the same touch electrode 140 at intervals in the first direction A and connecting the touch leads 150 to the middle portions of the plurality of touch electrode portions 141 of the corresponding touch electrodes 140 in the second direction B, to increase the touch accuracy of the display panel 100 and improve the touch performance of the display panel 100. In addition, this is conducive to reducing the display non-uniformity of the display panel 100.

In the embodiments of the present application, A being disposed corresponding to B may refer to that one A is disposed corresponding to at least one B, or one B is disposed corresponding to at least one A. The embodiments of the present application are described mainly with respect to an example in which one A is disposed corresponding to one B. For example, the touch leads 150 being disposed corresponding to the touch electrodes 140 may refer to that one touch lead 150 is disposed corresponding to at least one touch electrode 140, or one touch electrode 140 is disposed corresponding to at least one touch lead 150.

By way of example, at least part of the touch leads 150 are disposed in the same layer as the touch electrodes 140 to facilitate the simultaneous preparation of the at least part of the touch leads 150 and the touch electrodes 140, which is conducive to simplifying a preparation process of the at least part of the touch leads 150 and the touch electrodes 140 and reducing preparation costs.

In some embodiments, the orthographic projection of each of the touch electrodes 140 on the substrate 104 corresponds to a spacing between the orthographic projections of adjacent light-emitting units 1331 on the substrate 104. In other words, the orthographic projection of each of the touch electrodes 140 on the substrate 104 overlaps with the spacing between the orthographic projections of adjacent two of the light-emitting units 1331 on the substrate 104, thereby contributing to reducing the obstruction of the light-emitting units 1331 by the touch electrodes 140 to increase the light output rate of the display panel 100.

It should be noted that the orthographic projection of each of the touch electrodes 140 on the substrate 104 overlapping with the spacing between the orthographic projections of adjacent two of the light-emitting units 1331 on the substrate 104 may mean that the spacing between the orthographic projection of the touch electrode 140 on the substrate 104 partially or completely coincides with the spacing between the orthographic projections of the two adjacent light-emitting units 1331 on the substrate 104.

In some embodiments, referring to FIG. 3, the first electrode layer 131 includes a plurality of first electrode portions 1311, where the first electrode portions 1311 are disposed corresponding to the touch electrodes 140. The first electrode portions 1311 each include first sub-electrode portions 1311a and a plurality of second sub-electrode portions 1311b, where the first sub-electrode portions 1311a extend in the second direction B, and the plurality of second sub-electrode portions 1311b are arranged at intervals in the second direction B. In the first electrode portions 1311 and the corresponding touch electrodes 140, the second sub-electrode portions 1311b are disposed corresponding to the second spacings 162 between the touch electrodes 140, orthographic projections of the second sub-electrode portions 1311b on the substrate 104 overlap with orthographic projections of the corresponding second spacings 162 on the substrate 104. Each of the first electrode portions 1311 and the touch electrodes 140 may be formed of a layer of conductive material. The layer of conductive material is formed on sides of the light-emitting layer 133 and the first isolation structure 191 away from the substrate 104 during the preparation of the first electrode portions 1311 and the touch electrodes 140. Since the first isolation structure 191 has an undercut structure which isolates the layer of conductive material on the side of the first isolation structure 191 away from the substrate 104 from layers of conductive material in other regions, the layer of conductive material on the first isolation structure 191 forms the touch electrodes 140, and at least part of the layers of conductive material in other regions form the first electrode portions 1311, so the shapes of the orthographic projections of the first electrode portions 1311 on the substrate 104 are generally complementary to the shapes of the orthographic projections of the touch electrodes 140 on the substrate 104. In the first direction A, the first sub-electrode portions 1311a are located at ends of corresponding touch electrodes 140 away from corresponding touch leads 150, the first sub-electrode portions 1311a are connected to ends of the plurality of second sub-electrode portions 1311b away from the corresponding touch leads 150, to provide a first potential to the plurality of second sub-electrode portions 1311b through the first sub-electrode portions 1311a. In other words, the orthographic projections of the first sub-electrode portions 1311a on the substrate 104 are third orthographic projections, the orthographic projections of the second sub-electrode portions 1311b on the substrate 104 are fourth orthographic projections, and the orthographic projections of the touch leads 150 on the substrate 104 are fifth orthographic projections, where the third orthographic projections are connected to ends of the plurality of fourth orthographic projections away from corresponding fifth orthographic projections. As such, by connecting the touch leads 150 to the same ends of the plurality of touch electrode portions 141 of corresponding touch electrodes 140 in the first direction A, the first sub-electrode portions 1311a may be provided only at the ends of the touch electrodes 140 away from corresponding touch leads 150 in the first direction A, and it is not necessary to provide a structure for providing the first potential to the plurality of second sub-electrode portions 1311b on both sides of the touch electrodes 140 in the second direction B, and the distance between adjacent two of the touch electrodes 140 in the second direction B is small, which may reduce touch dead zones and be conducive to improving the touch accuracy of the display panel 100.

In some embodiments, the first sub-electrode portions 1311a of at least part of adjacent two of the first electrode portions 1311 in the second direction B are connected and the two adjacent first electrode portions 1311 in the second direction B are connected, to simultaneously provide the first potential to all the second sub-electrode portions 1311b of the two adjacent first electrode portions 1311 in the second direction B.

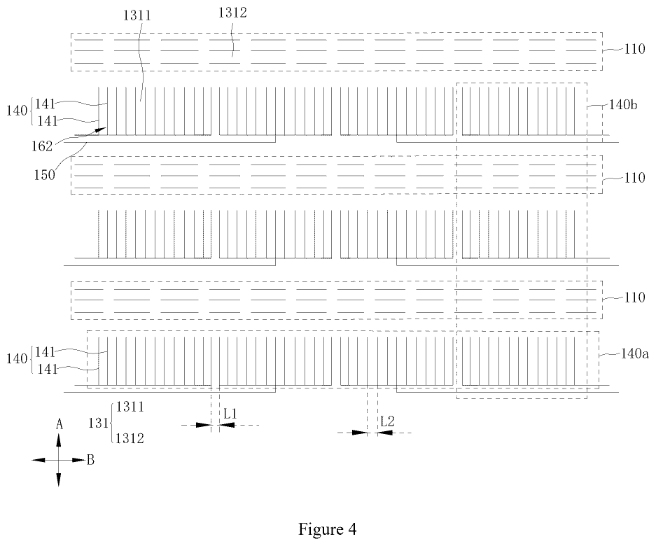

In some embodiments, in the plurality of touch electrodes 140 arranged in the second direction B, a minimum distance L1 (FIG. 4) between at least part of the adjacent touch electrodes 140 in the second direction B is equal to a minimum distance L2 in the second direction B between adjacent two of the touch electrode portions 141 of the same touch electrode 140 (FIG. 4). In this case, it is not necessary to provide a dummy electrode between the at least part of the adjacent touch electrodes 140, and it is also possible to make the display in the regions between the at least part of the adjacent touch electrodes 140 and in the regions where the at least part of the adjacent touch electrodes 140 are located appear more uniform to reduce the provision of dummy electrodes, and the distance between the at least part of the adjacent touch electrodes 140 is small and the touch dead zones can be reduced, which facilitates improving the touch accuracy of the display panel 100.

In some embodiments, referring to FIG. 2, the display panel 100 may include an active area 100a and a non-active area 100b, where the active area 100a may be used to display frames, and the non-active area 100b can be disposed adjacent to the active area 100a. The non-active area 100b can be located on at least one side of the active area 100a. For example, the non-active area 100b may be disposed around a periphery of the active area 100a, and the non-active area 100b may form a “black edge” around the periphery of the active area 100a.

By way of example, both the plurality of touch electrodes 140 and the plurality of touch leads 150 may be located in the active area 100a, and the touch leads 150 may also extend into the non-active area 100b. The display panel 100 includes a plurality of conductor wires 107. The plurality of conductor wires 107 are disposed corresponding to the plurality of touch leads 150, and the touch leads 150 are connected to the touch chip 105 by corresponding conductor wires 107.

In some embodiments, the display panel 100 includes the touch chip 105 and a flexible circuit board 106. The touch chip 105 is located in the non-active area 100b of the display panel 100, and the flexible circuit board 106 is located on sides of the touch chip 105 away from the touch electrodes 140.

In some embodiments, referring to FIG. 3, the display panel 100 includes a plurality of rows of touch electrodes 140a, where each row of touch electrodes 140a includes a plurality of touch electrodes 140 arranged in the second direction B, and the plurality of rows of touch electrodes 140a are arranged in the first direction A. The row of touch electrodes 140a contains a plurality of touch electrodes 140 arranged in a row in the second direction B.

In some embodiments, referring to FIG. 3, the display panel 100 includes a plurality of columns of touch electrodes 140b, where each column of touch electrodes 140b includes a plurality of touch electrodes 140 arranged in the first direction A, and the plurality of columns of touch electrodes 140b are arranged in the second direction B. The column of touch electrodes 140b contains a plurality of touch electrodes 140 arranged in a column in the first direction A.

In some embodiments, referring to FIG. 3, for the rows of touch electrodes 140a and the corresponding touch leads 150, the touch leads 150 are located on a side of the row of touch electrodes 140a in the first direction A, the first sub-electrode portions 1311a of the plurality of first electrode portions 1311 corresponding to the row of touch electrodes 140a are all located on the side of the row of touch electrodes 140a away from the touch leads 150, the first sub-electrode portions 1311a of the plurality of first electrode portions 1311 can be connected and the plurality of first electrode portions 1311 are connected, to simultaneously provide the first potential to all of the second sub-electrode portions 1311b of the plurality of first electrode portions 1311, thereby eliminating the need to provide a structure for providing the first potential to the plurality of second sub-electrode portions 1311b on each side of the touch electrodes 140 of the row of touch electrodes 140a in the second direction B, and a distance between adjacent two of the touch electrodes 140 of the row of touch electrodes 140a in the second direction B is small, which can reduce the touch dead zones and is conductive to improving the touch accuracy of the display panel 100.

In some embodiments, referring to FIG. 6, in adjacent two of the touch electrodes 140 in the second direction B, the two touch electrodes 140 are disposed opposite each other in the second direction B, and the arrangement of the two adjacent touch electrodes 140 is more regular, which is conductive to reducing the difficulty in disposing the two adjacent touch electrodes 140.

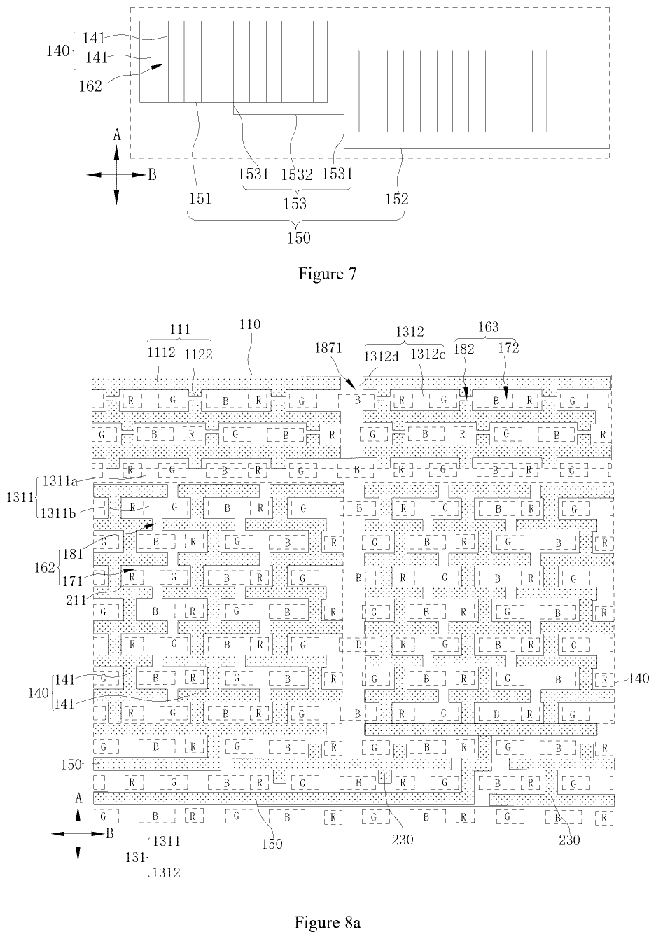

In other embodiments, referring to FIG. 7, in the adjacent two of the touch electrodes 140 in the second direction B, the two touch electrodes 140 are disposed partially opposite each other and partially misaligned with each other in the second direction B.

Touch electrode groups 140c according to the embodiments of the present application will be described below.

In some embodiments, referring to FIG. 3, the display panel 100 includes a plurality of touch electrode groups 140c, where each touch electrode group 140c includes two touch electrodes 140 arranged in the first direction A, and the touch leads 150 corresponding to the two touch electrodes 140 of the touch electrode group 140c are electrically connected. In other words, in the touch electrode group 140c and two corresponding touch leads 150, the two touch leads 150 are connected to the same conductor wire 107 and are connected to the touch chip 105 by the same conductor wire 107, which is conductive to reducing a load on a single touch electrode 140.

By way of example, in the touch electrode group 140c and the corresponding touch leads 150, the touch leads 150 are located between the two touch electrodes 140 of the touch electrode group 140c and the distance between the two touch leads 150 corresponding to the touch electrode group 140c is small, which is conductive to reducing the difficulty in connecting the two touch leads 150 corresponding to the touch electrode group 140c and the same conductor wire 107. In addition, in the touch electrode group 140c and the corresponding two first electrode portions 1311, the first sub-electrode portions 1311a of the two first electrode portions 1311 are located on two sides of the touch electrode group 140c in the first direction A, respectively, and it is not necessary to provide a first sub-electrode portion 1311a for providing the first potential between the two touch electrodes 140 of the touch electrode group 140c, and the distance between the two touch electrode portions 141 of the touch electrode group 140c is small, which can reduce the touch dead zones and is conductive to increasing the touch accuracy.

By way of example, the plurality of touch electrode groups 140c arranged in the second direction B form rows of touch electrode groups 140d. A plurality of rows of touch electrode groups 140d are provided, and the plurality of rows of touch electrode groups 140d are arranged at intervals in the first direction A.

The touch leads 150 according to the embodiments of the present application will be described below.

In some embodiments, orthographic projections of the plurality of touch leads 150 on the substrate 104 do not overlap with each other, thereby avoiding contact between adjacent two of the touch leads 150.

In some embodiments, referring to FIG. 6, each of the touch leads 150 includes a first sub-touch lead 151, where the first sub-touch lead 151 is in contact with a corresponding touch electrode 140. The same ends of the plurality of touch electrode portions 141 of the corresponding touch electrode 140 can be connected by the first sub-touch lead 151.

By way of example, the first sub-touch lead 151 may extend in the second direction B, and the first sub-touch lead 151 has a simple shape, which is conductive to reducing the difficulty in preparing the first sub-touch lead 151.

In some embodiments, referring to FIG. 6, the touch lead 150 includes a second sub-touch lead 152. The second sub-touch lead 152 extends in the second direction B in a direction away from a corresponding touch electrode 140, and the second sub-touch lead 152 is connected to a corresponding conductor wire 107.

In some embodiments, referring to FIG. 6, the touch lead 150 includes a third sub-touch lead 153. The third sub-touch lead 153 is located between the first sub-touch lead 151 and the third sub-touch lead 153, at least part of the third sub-touch lead 153 extends in a different direction from the first sub-touch lead 151 and the second sub-touch lead 152, and the first sub-touch lead 151 and the second sub-touch lead 152 are connected by the third sub-touch lead 153, which is conductive to keep the touch lead 150 away from an adjacent touch electrode 140 or other touch leads 150.

By way of example, referring to FIG. 6, the third sub-touch lead 153 extends in the first direction A, and the third sub-touch lead 153 has a simple shape, which is conductive to reducing the difficulty in preparing the third sub-touch lead 153.

By way of example, referring to FIG. 7, the third sub-touch lead 153 includes a first sub-lead 1531 and a second sub-lead 1532 arranged alternately and connected end-to-end. The first sub-lead 1531 extends in the first direction A, and the second sub-lead 1532 extends in the second direction B. The first sub-lead 1531 and the second sub-lead 1532 are provided and the third sub-touch lead 153 can be bent flexibly to allow the touch leads 150 to be adapted to various arrangements of the touch electrodes 140 and to avoid adjacent touch electrodes 140 and the other touch leads 150 while the third sub-touch lead 153 is close to structures such as the touch electrode 140 adjacent thereto, the other touch leads 150, etc. This is conductive to increasing the arrangement density of the touch electrodes 140 and the touch leads 150 and can reduce the touch dead zones and improve the touch accuracy. For example, referring to FIG. 7, the number of first sub-leads 1531 may be two, and the number of second sub-leads 1532 may be one.

In some embodiments, in the same row of touch electrodes 140a, the number of touch electrodes 140 is odd, and the plurality of touch electrodes 140 include an intermediate touch electrode that is in the middle. The non-active area 100b includes a first non-active area and a second non-active area on two sides of the second direction B. The touch leads 150 corresponding to the plurality of touch electrodes 140 located between the intermediate touch electrode and the first non-active area may each extend to the non-active area, the touch leads 150 corresponding to the plurality of touch electrodes 140 located between the intermediate touch electrode and the second non-active area may each extend to the second non-active area, and the touch lead 150 corresponding to the intermediate touch electrode may extend to the first non-active area or the second non-active area.

In other embodiments, in the same row of touch electrodes 140a, the number of touch electrodes 140 is even, the display panel 100 has a center line extending in the first direction A, the touch leads 150 corresponding to the plurality of touch electrodes 140 located between the center line and the first non-active area may each extend to the first non-active area, and the touch leads 150 corresponding to the plurality of touch electrodes 140 located between the center line and the second non-active area may each extend to the second non-active area.

In other embodiments, in the same row of touch electrodes 140a, the touch leads 150 corresponding to the plurality of touch electrodes 140 may each extend to either the first non-active area or the second non-active area.

The second spacing 162 according to the embodiments of the present application will be described below.

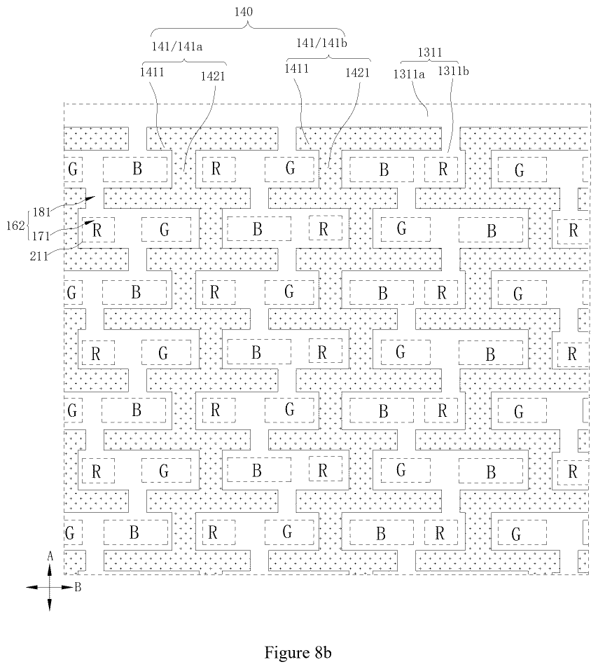

In some embodiments, referring to FIGS. 3, 8a and 8b, the second spacing 162 includes a plurality of first openings 171 and first gaps 181, where the plurality of first openings 171 are arranged at intervals in the first direction A, and adjacent two of the first openings 171 communicate with each other through the first gap 181. The first openings 171 are disposed corresponding to the light-emitting units 1331, and the orthographic projections of the light-emitting units 1331 on the substrate 104 overlap with the orthographic projections of the corresponding first openings 171 on the substrate 104, and light from the light-emitting units 1331 can exit through the first openings 171, which is conductive to reducing the influences of the touch electrodes 140 on light output from the light-emitting units 1331.

By way of example, the number of light-emitting units 1331 corresponding to any one of the first openings 171 may be at least one, for example, the number of light-emitting units 1331 corresponding to any one of the first openings 171 may be 1, 2, 3, 4, or any number greater than or equal to 5. The number of light-emitting units 1331 corresponding to any two of the first openings 171 may be the same or may be different.

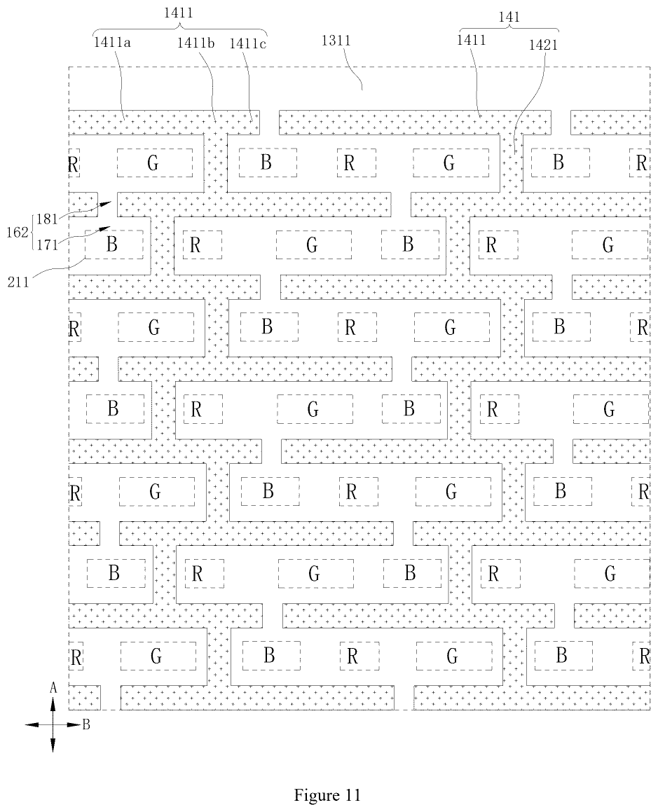

By way of example, at least part of the first openings 171 are disposed corresponding to at least two light-emitting units 1331 arranged in the second direction B. For example, referring to FIG. 8b, at least part of the first openings 171 are disposed corresponding to two light-emitting units 1331 arranged in the second direction B. For another example, referring to FIG. 11, at least part of the first openings 171 are disposed corresponding to three light-emitting units 1331 arranged in the second direction B.

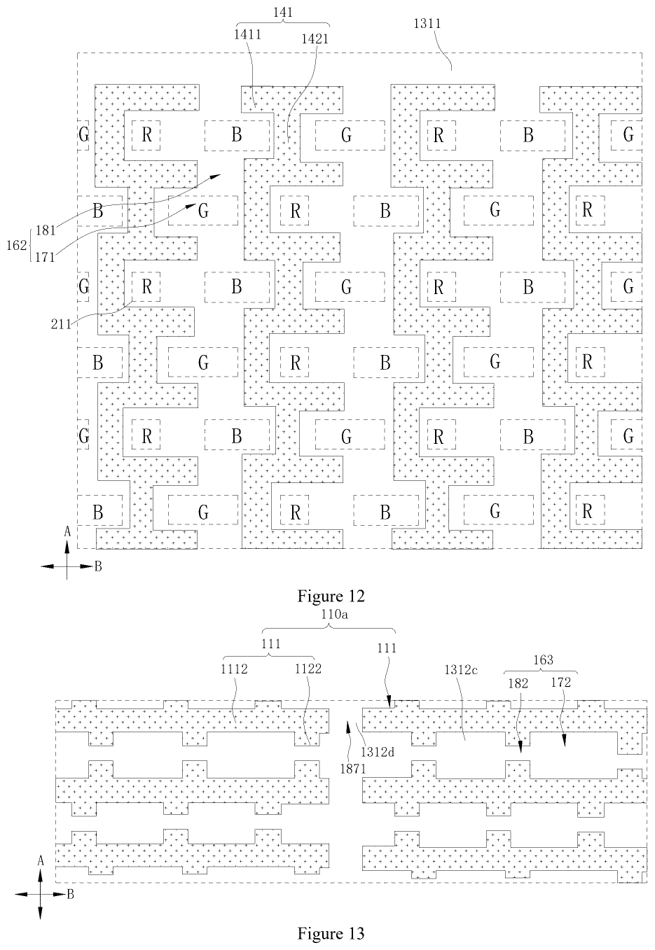

In some embodiments, referring to FIGS. 8b, 10 and 11, in two first openings 171 disposed adjacent to each other in the first direction A, each first opening 171 corresponds to the same number of light-emitting units 1331. Alternatively, referring to FIG. 12, in two first openings 171 disposed adjacent to each other in the first direction A, each first opening 171 corresponds to a different number of light-emitting units 1331.

By way of example, referring to FIG. 12, in two first openings 171 arranged adjacent to each other in the first direction A, the number of light-emitting units 1331 corresponding to one of the first openings 171 is 1, and the number of light-emitting units 1331 corresponding to the other of the first openings 171 is 2.

In some embodiments, referring to FIGS. 8b and 11, for a plurality of first gaps 181 between adjacent two of the touch electrode portions 141, adjacent two of the first gaps 181 are misaligned in the first direction A, and the regularity of the distribution of the plurality of first gaps 181 of the same second spacing 162 is reduced, which is conductive to reducing the visibility of the first gaps 181 to reduce the visibility of the pattern of the touch electrodes 140, to alleviate the phenomenon of bright and dark stripes of the display panel 100, which is conductive to improving the display effect of the display panel 100.

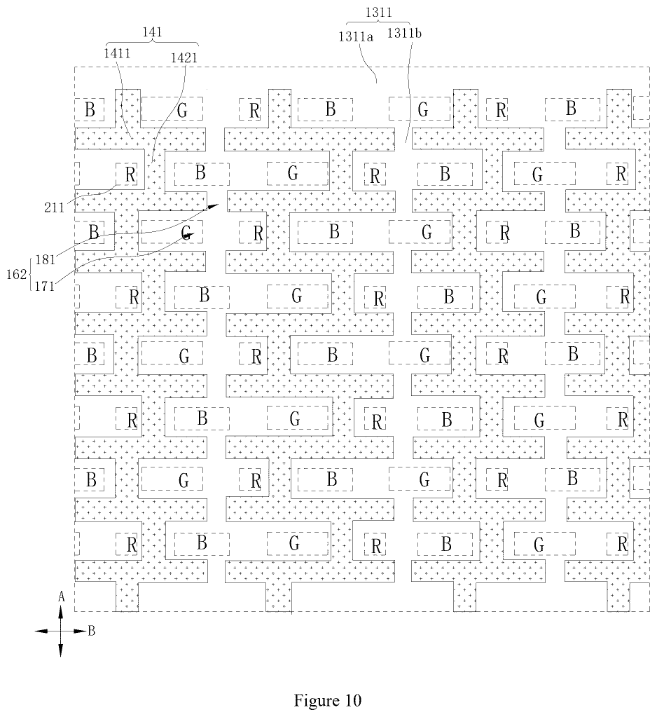

In some embodiments, referring to FIGS. 10 and 12, in the plurality of first gaps 181 between adjacent two of the touch electrode portions 141, adjacent two of the first gaps 181 are disposed opposite each other in the first direction A, and it is possible to reduce the difficulty in providing the first gaps 181. In addition, the shape of the orthographic projection of the second spacing 162 on the substrate 104 adapts to the shapes of the orthographic projections of the corresponding second sub-electrode portions 1311b on the substrate 104. The opposite arrangement of the two adjacent first gaps 181 in the first direction A is conductive to shorten a current transmission path for the second sub-electrode portions 1311b in the first direction A and to reducing the resistances of the second sub-electrode portions 1311b, reducing the voltage drop across the second sub-electrode portions 1311b.

By way of example, referring to FIGS. 10 and 12, in the plurality of first gaps 181 between adjacent two of the touch electrode portions 141, the first gaps 181 are arranged in a straight line, and the shape of the orthographic projection of the second spacing 162 on the substrate 104 adapts to the shapes of the orthographic projections of the corresponding second sub-electrode portions 1311b on the substrate 104. As such, the current transmission path for the second sub-electrode portions 1311b in the first direction A can be better shortened, to better reduce the resistances of the second sub-electrode portions 1311b and better reduce the voltage drop across the second sub-electrode portions 1311b.

In some embodiments, an orthographic projection of any one of the light-emitting units 1331 on the substrate 104 may be disposed opposite the orthographic projection of the first gap 181 on the substrate 104 in the first direction A. Alternatively, the orthographic projection of any one of the light-emitting units 1331 on the substrate 104 may be misaligned with the orthographic projection of the first gap 181 on the substrate 104 in the first direction A. For example, the orthographic projections of the first gaps 181 on the substrate 104 are first orthographic projections, and the orthographic projections of the light-emitting units 1331 on the substrate 104 are second orthographic projections. At least part of the second orthographic projections are disposed corresponding to the first orthographic projections, and the second orthographic projections are disposed opposite the corresponding first orthographic projections in the first direction A. The light output effects of the light-emitting units 1331 corresponding to the first gaps 181 are different from the light output effects of the light-emitting units 1331 not corresponding to the first gaps 181.

Referring to FIG. 8b, in the dashed box are shown an region in which pixel openings 211 corresponding to the light-emitting units 1331 are located, where the red light-emitting units are denoted by R, the green light-emitting units are denoted by G, and the blue light-emitting units are denoted by B.

In some embodiments, referring to FIG. 11, all of the light-emitting units 1331 corresponding to the second orthographic projections disposed opposite the first orthographic projections have the same luminous color, i.e., all of the first gaps 181 are disposed corresponding to the plurality of light-emitting units 1331 having the same color, and all of the first gaps 181 have an effect on the light output from the light-emitting elements 1331 of the same color and no effect on the light output from the light-emitting units 1331 of other colors, which results in uniform effects of the first gaps 181 on the light output from respective regions, improving the display uniformity of the display panel 100. For example, all of the light-emitting units 1331 corresponding to the second orthographic projections disposed opposite the first orthographic projections have a red, green, or blue luminous color.

In other embodiments, referring to FIGS. 8b and 10, for all of the light-emitting units 1331 corresponding to the second orthographic projections disposed opposite the first orthographic projections, at least part of the light-emitting units 1331 have different luminous colors. This can prevent all of the first gaps 181 from having effects on the light output from the light-emitting units 1331 of the same color which otherwise causes color cast to the display panel 100.

In some embodiments, referring to FIG. 8b, all of the light-emitting units 1331 corresponding to the second orthographic projections disposed opposite the first orthographic projections include first light-emitting units, second light-emitting units, and third light-emitting units. The first light-emitting units, the second light-emitting units and the third light-emitting units each have a different luminous color, and part of the first gaps 181 are disposed corresponding to the first light-emitting units, part of the first gaps 181 are disposed corresponding to the second light-emitting units, and part of the first gaps 181 are disposed corresponding to the third light-emitting units. The light outputs from the first light-emitting units, the second light-emitting units and the third light-emitting units are affected by the first gaps 181, and the color cast of the display panel 100 caused by the first gaps 181 can be further alleviated.

In some embodiments, referring to FIG. 8b, in the same touch electrode portion 141, the touch electrode portion 141 includes a plurality of first extension sections 1411 and a plurality of first connecting sections 1421, where the plurality of first extension sections 1411 are arranged at intervals in the first direction A, adjacent two of the first extension sections 1411 are connected by the first connecting section 1421, and the adjacent first extension sections 1411 extend in a different direction from the first connecting section 1421.

By way of example, the orthographic projection of the first extension section 1411 on the substrate 104 is at least partially located between the orthographic projections of two light-emitting units 1331 disposed adjacent to each other in the first direction A on the substrate 104, and the effects of the first extension section 1411 on the light output from the light-emitting units 1331 can be reduced, which is conductive to increasing the light output rate of the display panel 100.

By way of example, the orthographic projection of the first connecting section 1421 on the substrate 104 is at least partially located between the orthographic projections of two light-emitting units 1331 disposed adjacent to each other in the second direction B on the substrate 104, and the effects of the first connecting section 1421 on the light output from the light-emitting units 1331 can be reduced, which is conductive to increasing the light output rate of the display panel 100.

In some embodiments, referring to FIG. 8b, adjacent two of the touch electrode portions 141 are defined as a first touch electrode portion 141a and a second touch electrode portion 141b, respectively. The first extension section 1411 of the first touch electrode portion 141a is disposed corresponding to the first extension section 1411 of the second touch electrode portion 141b, there are first gaps 181 between the first extension sections 1411 of the first touch electrode portion 141a and the first extension sections 1411 of the corresponding second touch electrode portion 141b, and the first extension sections 1411 of the first touch electrode portion 141a are disposed opposite the first extension sections 1411 of the corresponding second touch electrode portion 141b in the second direction B. The first connecting sections 1421 of the first touch electrode portion 141a are disposed corresponding to the first connecting sections 1421 of the second touch electrode portion 141b, there is first openings 171 between the first connecting sections 1421 of the first touch electrode portion 141a and the first connecting sections 1421 of the corresponding second touch electrode portion 141b, and the first connecting sections 1421 of the first touch electrode portion 141a are disposed opposite the first connecting sections 1421 of the corresponding second touch electrode portion 141b in the second direction B.

By way of example, the first extension sections 1411 extend in the second direction B.

By way of example, the first connecting sections 1421 extend in the first direction A.

In some embodiments, referring to FIG. 12, in the same touch electrode portion 141, the same ends of the first extension sections 1411 of at least part of adjacent ones of the first extension sections 1411 in the second direction B are connected to the first connecting sections 1421.

In some embodiments, referring to FIG. 11, each of the first extension sections 1411 includes a first extension segment 1411a, a second extension segment 1411b, and a third extension segment 1411c arranged in sequence in the second direction B. In the same touch electrode portion 141, the second extension segments 1411b of adjacent two of the first extension sections 1411 are each connected to the first connecting sections 1421.

By way of example, the extension of the first extension segment 1411a in the second direction B may be different from or identical to the extension of the third extension segment 1411c in the second direction B, which is not limited in the embodiments of the present application.

Dummy electrodes according to the embodiments of the present application will be described below.

In some embodiments, referring to FIG. 4, the display panel 100 includes a plurality of dummy electrodes (a plurality of first dummy electrodes 110 and/or a plurality of second dummy electrodes 120 and/or a plurality of third dummy electrodes 230). The dummy electrodes and the touch electrodes 140 and the first electrode layer 131 are insulated from each other. The provision of the dummy electrodes enables to ensure that the display of the display panel 100 is relatively uniform in the regions where the touch electrodes 140 are provided and in the regions where the dummy electrodes are provided of the display panel 100, and the display uniformity of the display panel 100 can be improved.

In some embodiments, referring to FIG. 4, the plurality of dummy electrodes may include the plurality of first dummy electrodes 110. The first dummy electrodes 110 are disposed on one side of the substrate 104, the first dummy electrodes 110 are provided between at least part of adjacent rows of touch electrodes 140a.

By way of example, in a row of touch electrodes 140a and the corresponding touch leads 150, the touch leads 150 are located on a side of the row of touch electrodes 140a in the first direction A, the first dummy electrodes 110 are disposed corresponding to the row of touch electrodes 140a, and the first dummy electrodes 110 are located on the other side of the corresponding row of touch electrodes 140a in the first direction A.

Referring to FIG. 3, in an embodiment in which the touch electrode groups 140c are provided, the first dummy electrodes 110 are located on each side of the touch electrode groups 140c in the first direction A. As such, no first dummy electrode 110 is provided between every two touch electrodes 140 of the touch electrode groups 140c, which may reduce the number of first dummy electrodes 110 and advantageously provide touch accuracy. In an embodiment in which the rows of touch electrode groups 140d are provided, the rows of touch electrode groups 140d are provided with the first dummy electrodes 110 on each side in the first direction A.

In some embodiments, the first dummy electrodes 110 and the touch electrodes 140 are formed in the same layer with the same material, and the preparation process for the first dummy electrodes 110 and the touch electrodes 140 can be simplified and the preparation cost of the display panel 100 is reduced.

It should be noted that “formed in the same layer with the same material” in the embodiments of the present application refers to a base film layer formed of the same material, after the patterning and/or other processing of the base film layer, different parts of the base film layer form various structural film layers. The processes for forming the different structural film layers may be the same or different, and the different structural film layers formed may have the same or different thicknesses, and may also be in the same or different horizontal planes.

In some embodiments, referring to FIG. 3, in the same first dummy electrode 110, the first dummy electrode 110 includes a plurality of first dummy electrode portions 110a. The plurality of first dummy electrode portions 110a are arranged at intervals in the first direction A, with a third spacing 163 between adjacent two of the first dummy electrode portions 110a. The first electrode layer 131 includes a plurality of second electrode portions 1312. The second electrode portions 1312 are disposed corresponding to the first dummy electrodes 110. The first potential is supplied to the second electrode portions 1312, the second electrode portions 1312 are connected to the first sub-electrode portions 1311a of the first electrode portions 1311 adjacent thereto, and the first potential sequentially supplied to the first sub-electrode portions 1311a and the second sub-electrode portions 1311b of the first electrode portions 1311 in turn through the second electrode portions 1312.

By way of example, referring to FIG. 3, for the second electrode portions 1312 and the first dummy electrodes 110 that are disposed corresponding to each other, each of the second electrode portions 1312 includes a plurality of third sub-electrode portions 1312c. The third sub-electrode portions 1312c are disposed corresponding to the third spacings 163, orthographic projections of the third sub-electrode portions 1312c on the substrate 104 overlap with an orthographic projections of the third spacings 163 on the substrate 104, and the plurality of third sub-electrode portions 1312c are connected, and the second electrode portions 1312 are connected as one piece, which is conductive to reducing the resistances of the second electrode portions 1312 and reducing the voltage drop across the second electrode portions 1312.

By way of example, the shapes of the orthographic projections of the third sub-electrode portions 1312c on the substrate 104 adapt to the shapes of the orthographic projections of the third spacings 163 on the substrate 104.

By way of example, the orthographic projections of the first dummy electrodes 110 on the substrate 104 and the orthographic projections of the light-emitting units 1331 on the substrate 104 are spaced apart, which is conductive to reducing the obstruction of the light-emitting units 1331 by the first dummy electrodes 110 and to improving the light output rate of the display panel 100.

In some embodiments, referring to FIG. 3, in the same first dummy electrode portion 110a, the first dummy electrode portion 110a includes a plurality of first sub-portions 111 arranged at intervals in the second direction B, and there is a first auxiliary gap 1871 between adjacent two of the first sub-portions 111. For the second electrode portions 1312 and the first dummy electrodes 110 that are disposed corresponding to each other, each of the second electrode portions 1312 includes fourth sub-electrode portions 1312d. The fourth sub-electrode portions 1312d are disposed corresponding to the first auxiliary gaps 1871, the orthographic projections of the fourth sub-electrode portions 1312d on the substrate 104 overlap with the orthographic projections of the first auxiliary gaps 1871 on the substrate 104, and adjacent two of the third sub-electrode portions 1312c are connected by the fourth sub-electrode portion 1312d located between the two adjacent third sub-electrode portions 1312c, and the second electrode portions 1312 are connected as one piece.

By way of example, the shapes of the orthographic projections of the fourth sub-electrode portions 1312d on the substrate 104 adapt to the shapes of the orthographic projections of the first auxiliary gaps 1871 on the substrate 104.

In some embodiments, referring to FIG. 3, in adjacent two of the first dummy electrode portions 110a, the first auxiliary gap 1871 of one of the first dummy electrode portions 110a is disposed opposite the first auxiliary gap 1871 of the other of the first dummy electrode portions 110a in the first direction A, and the arrangement of the first auxiliary gaps 1871 is more regular, which is conductive to reduce the difficulty in providing the first auxiliary gaps 1871.

In some embodiments, referring to FIGS. 3, 13 and 15, in the same first sub-portion 111, the first sub-portion 111 includes a second extension section 1112. The second extension section 1112 extends in the second direction B, and the second extension section 1112 has a simple shape, which is conductive to reducing the difficulty in providing the second extension section 1112. For example, referring to FIG. 15, the first sub-portion 111 is formed entirely by the second extension section 1112. Alternatively, referring to FIG. 13, the first sub-portion 111 is partially formed by the second extension section 1112.

Referring to FIG. 15, in an embodiment in which the first sub-portion 111 is formed entirely by the second extension section 1112, the dimensions of the third spacings 163 in the first direction A are identical in the second direction B, thereby reducing the difficulty in preparing the third spacings 163 and the preparation costs. In addition, the shapes of the orthographic projections of the third sub-electrode portions 1312c on the substrate 104 adapt to the shapes of the orthographic projections of the third spacings 163 on the substrate 104, and the shapes of the third sub-electrode portions 1312c can be simple and the widths of parts of the third sub-electrode portion 1312c (i.e. the dimensions in the first direction A) are large, which is conductive to reducing the resistances of the third sub-electrode portions 1312c and the voltage drop across the third sub-electrode portions 1312c.

In some embodiments, referring to FIG. 13, in the same first sub-portion 111, the first sub-portion 111 includes a plurality of second connecting sections 1122 connected to the second extension section 1112. On the same side of the second extension section 1112 in the first direction A, the plurality of second connecting sections 1122 are arranged at intervals in the second direction B. The provision of the second connecting sections 1122 results in that the topographies of the first dummy electrodes 110 are more similar to the topographies of the touch electrodes 140. This can further improve the display uniformity of the display panel 100 in the regions in which the first dummy electrodes 110 are located and in the regions in which the touch electrodes 140 are located.

By way of example, the orthographic projection of the second extension section 1112 on the substrate 104 is at least partially located between the orthographic projections of adjacent two of the light-emitting units 1331 in the first direction A on the substrate 104, and the effects of the second extension section 1112 on the light output from the light-emitting units 1331 can be reduced, which is conductive to increasing the light output rate of the display panel 100.

By way of example, the orthographic projection of the second connecting section 1122 on the substrate 104 is at least partially located between the orthographic projections of adjacent two of the light-emitting units 1331 in the second direction B on the substrate 104, and the effects of the second connecting section 1122 on the light output from the light-emitting units 1331 can be reduced, which is conductive to increasing the light output rate of the display panel 100.

In some embodiments, referring to FIG. 13, each of the third spacings 163 includes a plurality of second openings 172 and second gaps 182, where the plurality of second openings 172 are arranged at intervals in the second direction B, and adjacent two of the second openings 172 communicate with each other through the second gap 182. The second openings 172 are disposed corresponding to the light-emitting units 1331, and the orthographic projections of the light-emitting units 1331 on the substrate 104 overlap with the orthographic projections of the corresponding second openings 172 on the substrate 104, and light from the light-emitting units 1331 can exit through the second openings 172.

In some embodiments, referring to FIG. 13, in adjacent two of the first sub-portions 111 in the first direction A, the second connecting section 1122 of one of the first sub-portions 111 is disposed corresponding to the second connecting section 1122 of the other of the first sub-portions 111, there is a second gap 182 between the second connecting section 1122 of one of the first sub-portions 111 and the corresponding second connecting section 1122 of the other of the first sub-portions 111, and the second connecting section 1122 of one of the first sub-portions 111 is disposed opposite the corresponding second connecting section 1122 of the other of the first sub-portions 111 in the first direction A. There are a plurality of second openings 172 between the second extension section 1112 of one of the first sub-portions 111 and the second extension section 1112 of the other of the first sub-portions 111, and the second extension section 1112 of one of the first sub-portions 111 is disposed opposite the second extension section 1112 of the other of the first sub-portions 111 in the first direction A.

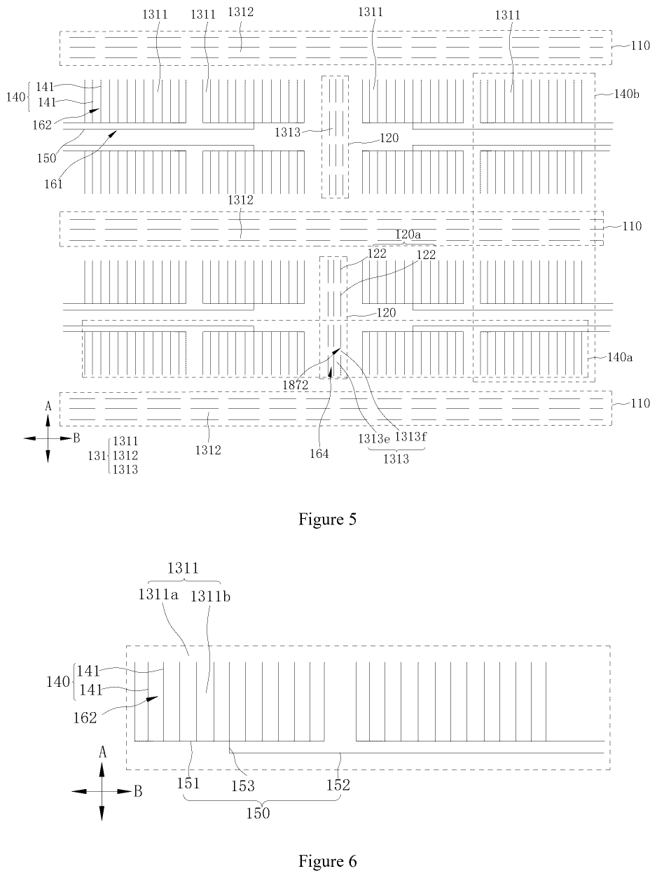

In some embodiments, referring to FIG. 5, the display panel 100 further includes second dummy electrodes 120, where the second dummy electrodes 120 are disposed on a side of the substrate 104. A plurality of second dummy electrodes 120 are provided. One second dummy electrode 120 is provided between adjacent two of the first dummy electrode portions 110a, and the number of second dummy electrodes 120 between the adjacent two of the first dummy electrode portions 110a is small. The plurality of second dummy electrodes 120 are arranged in a column of second dummy electrodes in the first direction A. One column of second dummy electrodes may be provided. As such, the number of columns of second dummy electrodes is small, which can reduce the touch dead zones and the effects of the column of second dummy electrodes on the touch accuracy.

In some other embodiments, the display panel 100 may also be provided with no second dummy electrodes 120, and the touch dead zones can be further reduced and the effects of the column of second dummy electrodes 120 on the touch accuracy are further reduced.

In some embodiments, the number of columns of touch electrodes 140b is odd. The plurality of columns of touch electrodes 140b include adjacent first and second columns of touch electrodes. The first column of touch electrodes is in the middle among all the columns of touch electrodes. The second dummy electrodes 120 are located between the first and second columns of touch electrodes, and interferences between the layouts of the second dummy electrodes 120 and the touch leads 150 can be avoided.

In some embodiments, the number of columns of touch electrodes 140b is even. The plurality of columns of touch electrodes 140b include adjacent third and fourth columns of touch electrodes. The third and fourth columns of touch electrodes are in the middle among all the columns of touch electrodes 140b. The second dummy electrodes 120 are located between the third and fourth columns of touch electrodes, and interferences between the layouts of the second dummy electrodes 120 and the touch leads 150 can be avoided.

In some embodiments, referring to FIG. 5, each of the second dummy electrodes 120 includes a plurality of second dummy electrode portions 120a, where the plurality of second dummy electrode portions 120a are arrange at intervals in the second direction B. There is a fourth spacing 164 between adjacent two of the second dummy electrode portions 120a. The first electrode layer 131 includes a plurality of third electrode portions 1313. The third electrode portions 1313 are disposed corresponding to the second dummy electrodes 120. For the third electrode portions 1313 and the second dummy electrodes 120 that are disposed corresponding to each other, each of the third electrode portions 1313 includes a plurality of fifth sub-electrode portions 1313e. The fifth sub-electrode portions 1313e are disposed corresponding to the fourth spacings 164, orthographic projections of the fifth sub-electrode portions 1313e on the substrate 104 overlap with orthographic projections of the fourth spacings 164 on the substrate 104, and the plurality of fifth sub-electrode portions 1313e are connected, and the third electrode portions 1313 are connected as one piece, which is conductive to reducing the resistances of the third electrode portions 1313 and reducing the voltage drop across the third electrode portions 1313.

By way of example, the shape of the orthographic projections of the fifth sub-electrode portions 1313e on the substrate 104 adapts to the shape of the orthographic projections of the fourth spacings 164 on the substrate 104.

In some embodiments, in the same second dummy electrode portion 120a, the second dummy electrode portion 120a includes a plurality of second sub-portions 122 arranged at intervals in the first direction A, and there is a second auxiliary gap 1872 between adjacent two of the second sub-portions 122. Each of the third electrode portions 1313 includes sixth sub-electrode portions 1313f. The sixth sub-electrode portions 1313f are disposed corresponding to the second auxiliary gaps 1872, the orthographic projections of the sixth sub-electrode portions 1313f on the substrate 104 overlap with the orthographic projections of the second auxiliary gaps 1872 on the substrate 104, and adjacent two of the fifth sub-electrode portions 1313e are connected by the sixth sub-electrode portion 1313f located between the two adjacent fifth sub-electrode portions 1313e, and the third electrode portions 1313 are connected as one piece.

By way of example, the shapes of the orthographic projections of the sixth sub-electrode portions 1313f on the substrate 104 adapt to the shape of the orthographic projections of the second auxiliary gaps 1872 on the substrate 104.

In some embodiments, in adjacent two of the second dummy electrode portions 120a, the second auxiliary gaps 1872 of one of the second dummy electrode portions 120a are disposed opposite the second auxiliary gaps 1872 of the other of the second dummy electrode portions 120a in the second direction B, and the arrangement of the second auxiliary gaps 1872 is more regular, which is conductive to reduce the difficulty in providing the second auxiliary gaps 1872.

In some embodiments, referring to the figures, the adjacent second electrode portions 1312 and the third electrode portion 1313 located between the two adjacent second electrode portions 1312 are connected and all of the second electrode portions 1312 can be connected as one piece by the plurality of third electrode portions 1313, which is conductive to reducing the resistance of the second electrode portions 1312, to reduce the voltage drop across the second electrode portions 1312. In addition, since the second electrode portions 1312 are connected to an adjacent row of first electrode portions 1311, the first electrode portions 1311, the second electrode portions 1312, and the third electrode portions 1313 are connected as one piece, which is conductive to connecting the first electrode layer 131 as a continuous electrode.

It should be noted that the third electrode portions 1313 may be provided even if no second dummy electrode 120 is provided. One third electrode portion 1313 may be provided between adjacent two of the second electrode portions 1312, and the adjacent second electrode portions 1312 are connected to the third electrode portion 1313 between the two adjacent second electrode portions 1312. In this case, the third electrode portions 1313 can be shaped simply, and the third electrode portions 1313 may be dimensioned to be small in the second direction B, which is conducive to improving the touch accuracy.

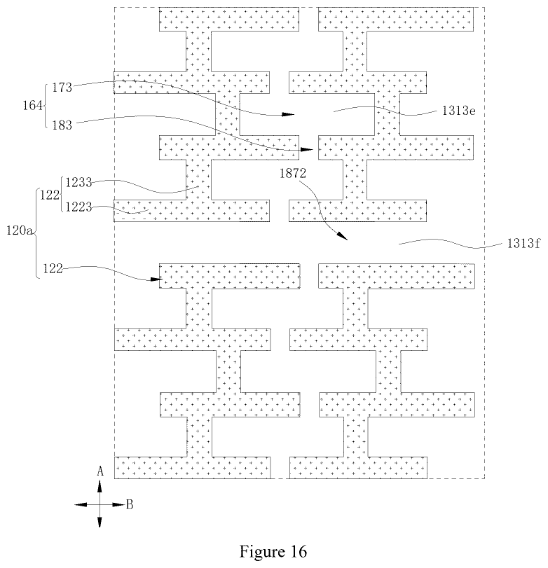

In some embodiments, referring to FIG. 16, each of the fourth spacings 164 includes a plurality of third openings 173 and third gaps 183, where the plurality of third openings 173 are arranged at intervals in the first direction A, and adjacent two of the third openings 173 communicate with each other through the third gap 183. The third openings 173 are disposed corresponding to the light-emitting units 1331, and the orthographic projections of the light-emitting units 1331 on the substrate 104 overlap with the orthographic projections of the corresponding third openings 173 on the substrate 104, and light from the light-emitting units 1331 can exit through the third openings 173.

In some embodiments, the orthographic projections of the second dummy electrodes 120 on the substrate 104 and the orthographic projections of the light-emitting units 1331 on the substrate 104 are spaced apart, and the obstruction of the light-emitting units 1331 by the second dummy electrodes 120 can be reduced, which is conductive to improving the light output rate of the display panel 100.

In some embodiments, the second dummy electrodes 120 and the touch electrodes 140 are formed in the same layer with the same material, and the preparation process for the second dummy electrodes 120 and the touch electrodes 140 is simplified and the preparation cost of the display panel 100 is reduced.

In some embodiments, referring to FIG. 16, in the same second sub-portion 122, the second sub-portion 122 includes a plurality of third extension sections 1223 and third connecting sections 1233, where the plurality of third extension sections 1223 are arranged at intervals in the first direction A, and adjacent two of the third extension sections 1223 are connected by the third connecting section 1233. The adjacent third extension sections 1223 extend in a different direction from the third connecting section 1233.

By way of example, the third extension sections 1223 extend in the second direction B.

By way of example, the third connecting sections 1233 extend in the first direction A.

In some embodiments, the orthographic projection of the third extension section 1223 on the substrate 104 is at least partially located between the orthographic projections of adjacent two of the light-emitting units 1331 in the first direction A on the substrate 104, and the effects of the third extension section 1223 on the light output from the light-emitting units 1331 can be reduced, which is conductive to increasing the light output rate of the display panel 100.

In some embodiments, the orthographic projection of the third connecting section 1233 on the substrate 104 is at least partially located between orthographic projections of adjacent two of the light-emitting units 1331 in the second direction B on the substrate 104, and the effects of the third connecting section 1233 on the light output from the light-emitting units 1331 can be reduced, which is conductive to increasing the light output rate of the display panel 100.

In some embodiments, in adjacent two of the second sub-portions 122 in the second direction B, the third connecting section 1233 of one of the second sub-portions 122 is disposed corresponding to the third connecting section 1233 of the other of the second sub-portions 122, there is a third opening 173 between the third connecting section 1233 of one of the second sub-portions 122 and the corresponding third connecting section 1233 of the other of the second sub-portions 122, and the third connecting section 1233 of one of the second sub-portions 122 is disposed opposite the corresponding third connecting section 1233 of the other of the second sub-portions 122 in the second direction B. The third extension section 1223 of one of the second sub-portions 122 is disposed corresponding to the third extension section 1223 of the other of the second sub-portions 122, there are a plurality of third gaps 183 between the third extension section 1223 of one of the second sub-portions 122 and the third extension section 1223 of the other of the second sub-portions 122, and the third extension section 1223 of one of the second sub-portions 122 is disposed opposite the third extension section 1223 of the other of the second sub-portions 122 in the second direction B.

Referring to FIG. 8a, the plurality of dummy electrodes may include a plurality of third dummy electrodes 230. The third dummy electrodes 230 may be located on at least one side of the touch leads 150, e.g., each of the third dummy electrodes 230 may be located between adjacent two of the touch leads 150, and the display of the display panel in a region between the two adjacent touch leads 150 and a region where the touch electrodes 140 are located may be uniform, improving the display uniformity of the display panel.

The isolation structure according to the embodiments of the present application will be described below.

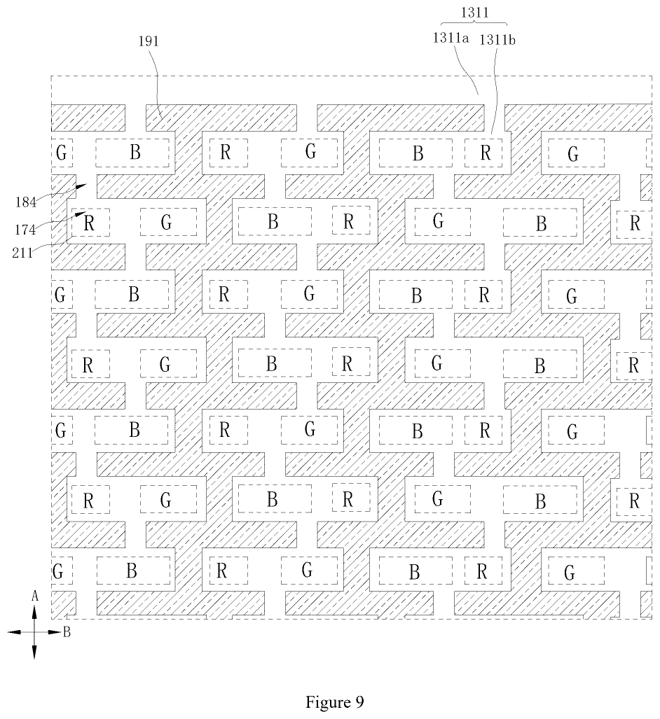

In some embodiments, referring to FIGS. 1 and 9, the display panel 100 includes at least one isolation structure (i.e., at least one of a first isolation structure 191, a second isolation structure 192 and a third isolation structure 193). The at least one isolation structure includes the first isolation structure 191, the touch electrodes 140 are located on a side of the first isolation structure 191 away from the substrate 104, the first isolation structure 191 encloses a plurality of fourth openings 174 and fourth gaps 184, adjacent two of the fourth openings 174 in the first direction A communicate with each other through the fourth gap 184, the second sub-electrode portions 1311b of the first electrode portions 1311 are located in the fourth openings 174 and the fourth gaps 184, and the second sub-electrode portions 1311b located in the two adjacent fourth openings 174 in the first direction A are connected by the second sub-electrode portion 1311b located in the fourth gap 184.

In some embodiments, the first electrode layer 131 and the touch electrodes 140 are formed in the same layer with the same material, and the preparation process for the first electrode layer 131 and the touch electrodes 140 can be simplified and the preparation cost of the display panel 100 is reduced. In the related art, when an On cell structure is used for touch control, it is necessary to prepare a multi-layer structure on an encapsulation layer to form the touch electrodes. In the embodiments of the present application, the touch electrodes 140 and the first electrode layer 131 being formed in the same layer with the same material is conductive to reducing the number of film layers of the display panel 100, simplifying the manufacturing process of the display panel 100 and reducing the thickness and cost of the display panel 100.

In some embodiments, the first isolation structure 191 may refer to an undercut structure with a bigger top and a smaller bottom that can isolates the touch electrodes 140 from the first electrode layer 131. The isolation structure can be a structure formed by a single film layer or a structure formed by a stack of a plurality of film layers.

By way of example, the cross-section of the isolation structure may be in the form of an inverted trapezoid with a bigger top and a smaller bottom, a T, an I, etc.

In some embodiments, by separating the touch electrodes 140 from the first electrode layer 131 by the first isolation structure 191, the shape of the orthographic projection of the first isolation structure 191 on the substrate 104 can be simply implemented to adapt (e.g., identical) to the shapes of the orthographic projections of the touch electrodes 140 on the substrate 104, to control the shapes of the formed touch electrodes 140 by controlling the shape of the first isolation structure 191. In addition, since the second sub-electrode portions 1311b are located in the fourth openings 174 and the fourth gaps 184, the shapes of the fourth openings 174 and the fourth gaps 184 can be controlled by controlling the shape of the first isolation structure 191, to control the shapes of the second sub-electrode portions 1311b.

By way of example, referring to FIGS. 8b and 9, the fourth openings 174 are disposed corresponding to the first openings 171, and orthographic projections of the fourth openings 174 on the substrate 104 overlap (e.g., fully coincide) with orthographic projections of the corresponding first openings 171 on the substrate 104, the fourth gaps 184 are disposed corresponding to the first gaps 181, and orthographic projections of the fourth gaps 184 on the substrate 104 overlap (e.g., fully coincide) with orthographic projections of the corresponding first gaps 181 on the substrate 104.

By way of example, referring to FIG. 1, the first isolation structure 191 includes a first isolating portion 1911 and a second isolating portion 1912. The second isolating portion 1912 is disposed on a side of the first isolating portion 1911 facing the substrate 104. An orthographic projection of the second isolating portion 1912 on the substrate 104 is disposed within an orthographic projection of the first isolating portion 1911 on the substrate 104 and the first isolation structure 191 forms an undercut structure with a bigger top and a smaller bottom, that is, the isolation structure has an “eave”. As such, during the formation of the touch electrodes 140 and the first electrode layer 131, the first isolation structure 191 may isolate the touch electrodes 140 from the first electrode layer 131.

In some embodiments, a material of at least one of the first isolating portion 1911 and the second isolating portion 1912 includes an insulating material, which is conductive to prevention of short-circuiting of the touch electrodes 140 and the first electrode layer 131.

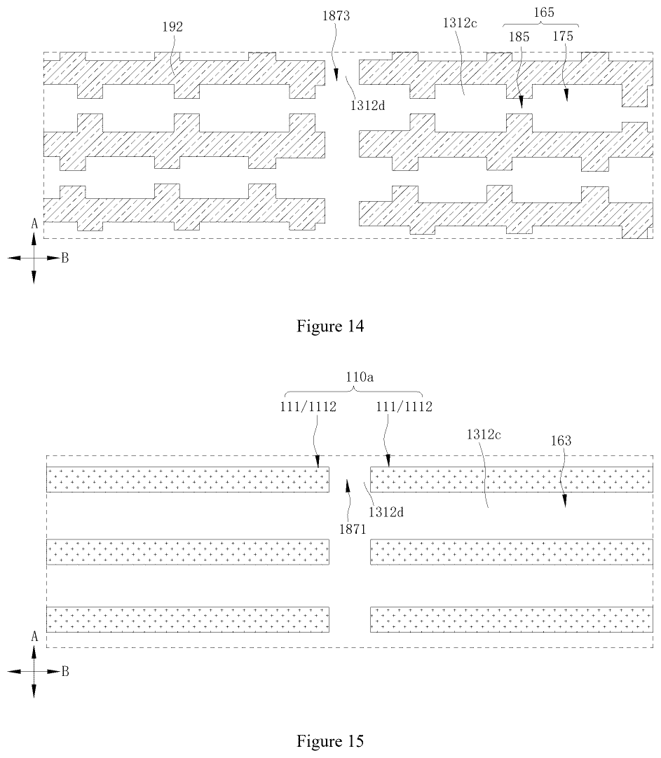

In some embodiments, referring to FIG. 14, the at least one isolation structure may include the second isolation structure 192. The second isolation structure 192 is located between the substrate 104 and the first dummy electrodes 110. The provision of the second isolation structure 192 allows the first dummy electrodes 110 to be isolated from the first electrode layer 131.

By way of example, referring to FIG. 14, the second isolation structure 192 encloses fifth spacings 165 and third auxiliary gaps 1873 in communication with each other. The third sub-electrode portions 1312c of the second electrode portions 1312 are located in the fifth spacings 165. The fourth sub-electrode portions 1312d of the second electrode portions 1312 are located in the third auxiliary gaps 1873. When a plurality of fifth spacings 165 are provided, the third sub-electrode portions 1312c in adjacent two of the fifth spacings 165 are connected by the fourth sub-electrode portion 1312d in the third auxiliary gap 1873.

By way of example, referring to FIGS. 13 and 14, the third spacings 163 are disposed corresponding to the fifth spacings 165, the orthographic projections of the third spacings 163 on the substrate 104 overlap with orthographic projections of the corresponding fifth spacings 165 on the substrate 104, the first auxiliary gaps 1871 are disposed corresponding to the third auxiliary gaps 1873, and the orthographic projections of the first auxiliary gaps 1871 on the substrate 104 overlap with orthographic projections of the corresponding third auxiliary gaps 1873 on the substrate 104. For example, the orthographic projections of the third spacings 163 on the substrate 104 coincide exactly with the orthographic projections of the corresponding fifth spacings 165 on the substrate 104, and the orthographic projections of the first auxiliary gaps 1871 on the substrate 104 coincide exactly with the orthographic projections of the corresponding third auxiliary gaps 1873 on the substrate 104. The shapes of the fifth spacings 165 and the third auxiliary gaps 1873 are controlled by controlling the shape of the second isolation structure 192, to control the shapes of the third spacings 163 and the first auxiliary gaps 1871 and the shapes of the second electrode portions 1312.

By way of example, referring to FIG. 14, the fifth spacings 165 each include a plurality of fifth openings 175 and fifth gaps 185. The plurality of fifth openings 175 are arranged at intervals in the second direction B. Adjacent two of the fifth openings 175 in the second direction B communicate with each other through the fifth gap 185. The third sub-electrode portions 1312c of the second electrode portions 1312 are located in the fifth openings 175 and the fifth gaps 185.

By way of example, by isolating the first dummy electrodes 110 from the first electrode layer 131 by the second isolation structure 192, the shape of the orthographic projection of the second isolation structure 192 on the substrate 104 can be simply implemented to adapt (e.g., identical) to the shapes of the orthographic projections of the first dummy electrodes 110 on the substrate 104, to control the shapes of the first dummy electrodes 110 by controlling the shape of the second isolation structure 192.

By way of example, referring to FIGS. 13 and 14, the fifth openings 175 are disposed corresponding to the second openings 172, and orthographic projections of the fifth openings 175 on the substrate 104 overlap (e.g., fully coincide) with the orthographic projections of the corresponding second openings 172 on the substrate 104, the fifth gaps 185 are disposed corresponding to the second gaps 182, and orthographic projections of the fifth gaps 185 on the substrate 104 overlap (e.g., fully coincide) with orthographic projections of the corresponding second gaps 182 on the substrate 104.

In some embodiments, the first isolation structure 191 and the second isolation structure 192 are formed in the same layer with the same material, and the preparation process for the first isolation structure 191 and the second isolation structure 192 can be simplified and the preparation cost of the display panel 100 is reduced.

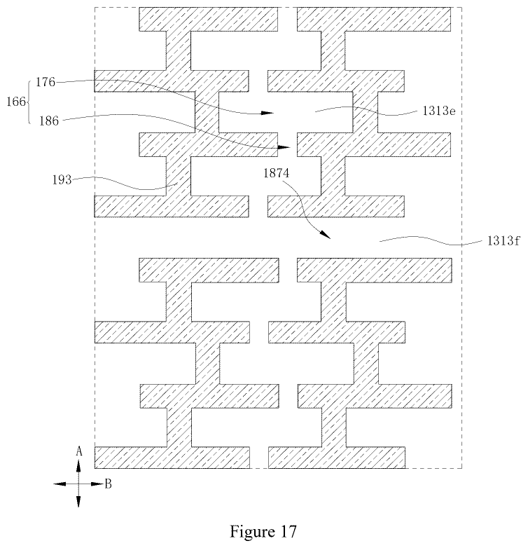

In some embodiments, referring to FIG. 17, the at least one isolation structure includes a third isolation structure 193. The third isolation structure 193 is located between the substrate 104 and the second dummy electrodes 120. The third isolation structure 193 can isolate the second dummy electrodes 120 from the first electrode layer 131.

By way of example, referring to FIG. 17, the third isolation structure 193 encloses sixth spacings 166 and fourth auxiliary gaps 1874 in communication with each other. The fifth sub-electrode portions 1313e of the third electrode portions 1313 are located in the sixth spacings 166. The sixth sub-electrode portions 1313f of the third electrode portions 1313 are located in the fourth auxiliary gaps 1874. When a plurality of sixth spacings 166 are provided, the fifth sub-electrode portions 1313e in adjacent two of the sixth spacings 166 are connected by the sixth sub-electrode portion 1313f in the fourth auxiliary gap 1874.

By way of example, referring to FIGS. 16 and 17, the fourth spacings 164 are disposed corresponding to the sixth spacings 166, the orthographic projections of the fourth spacings 164 on the substrate 104 overlap with orthographic projections of the corresponding sixth spacings 166 on the substrate 104, the second auxiliary gaps 1872 are disposed corresponding to the fourth auxiliary gaps 1874, and the orthographic projections of the second auxiliary gaps 1872 on the substrate 104 overlap with orthographic projections of the corresponding fourth auxiliary gaps 1874 on the substrate 104. For example, the orthographic projections of the fourth spacings 164 on the substrate 104 coincide exactly with the orthographic projections of the corresponding sixth spacings 166 on the substrate 104, and the orthographic projections of the second auxiliary gaps 1872 on the substrate 104 coincide exactly with the orthographic projections of the corresponding fourth auxiliary gaps 1874 on the substrate 104. The shapes of the sixth spacings 166 and the fourth auxiliary gaps 1874 are controlled by controlling the shape of the third isolation structure 193, to control the shapes of the fourth spacings 164 and the second auxiliary gaps 1872 and the shapes of the third electrode portions 1313.

By way of example, referring to FIG. 17, the sixth spacings 166 each include a plurality of sixth openings 176 and sixth gaps 186. The plurality of sixth openings 176 are arranged at intervals in the first direction A. Adjacent two of the sixth openings 176 in the first direction A communicate with each other through the sixth gap 186. The fifth sub-electrode portions 1313e of the third electrode portions 1313 are located in the sixth openings 176 and the sixth gaps 186.

By way of example, by isolating the second dummy electrodes 120 from the first electrode layer 131 by the third isolation structure 193, the shape of the orthographic projection of the third isolation structure 193 on the substrate 104 can be simply implemented to adapt (e.g., identical) to the shapes of the orthographic projections of the second dummy electrodes 120 on the substrate 104, to control the shapes of the second dummy electrodes 120 by controlling the shape of the third isolation structure 193.

By way of example, referring to FIGS. 16 and 17, the sixth openings 176 are disposed corresponding to the third openings 173, and orthographic projections of the sixth openings 176 on the substrate 104 overlap (e.g., fully coincide) with the orthographic projections of the corresponding third openings 173 on the substrate 104, the sixth gaps 186 are disposed corresponding to the third gaps 183, and orthographic projections of the sixth gaps 186 on the substrate 104 overlap (e.g., fully coincide) with orthographic projections of the corresponding third gaps 183 on the substrate 104.

In some embodiments, the first isolation structure 191 and the third isolation structure 193 are formed in the same layer with the same material, and the preparation process for the first isolation structure 191 and the third isolation structure 193 can be simplified and the preparation cost of the display panel 100 is reduced.

In some embodiments, referring to FIG. 1, the display panel 100 may further include a pixel defining layer 210. The pixel defining layer 210 may be disposed between the isolation structure (taking the first isolation structure 191 as an example) and the substrate 104. The pixel defining layer 210 defines a plurality of pixel openings 211, the light-emitting units 1331 are disposed corresponding to the pixel openings 211, and at least part of the light-emitting units 1331 may be located within the corresponding pixel openings 211.

In some embodiments, referring to FIG. 1, the display panel 100 includes a first encapsulation layer 101. The first encapsulation layer 101 is located on sides of the touch electrodes 140 and the light-emitting units 1331 away from the substrate 104.

In some embodiments, referring to FIG. 1, the display panel 100 may include a second encapsulation layer 102 on a side of the first encapsulation layer 101 away from the substrate 104.

In some embodiments, the display panel 100 may include a third encapsulation layer 103 on a side of the second encapsulation layer 102 away from substrate 104.

By way of example, a material of at least one of the first encapsulation layer 101 and the third encapsulation layer 103 may include an inorganic material. The encapsulation layer of the inorganic material has a better barrier effect on moisture and oxygen, allowing for a better encapsulation effect.

By way of example, a material of the second encapsulation layer 102 may include an organic material, which is beneficial for the stress relief of the film layers.

When the terms “comprise”, “have”, and “include” are used as described herein, unless otherwise clearly defined, for example, expressions “only” and “composed of . . . ”, another component may further be added. Unless otherwise mentioned, the singular form may include plural forms and should not be construed as the number thereof being one.

The above embodiments may be randomly combined. To make the description concise, not all possible combinations of the features in the above embodiments are described. However, the combinations of these features shall be considered as falling within the scope recorded in this specification provided that no conflict exists.

The above embodiments merely represent several implementations of the present application, giving specifics and details thereof, but should not be understood as limiting the scope of patent of the present application. It should be noted that several alterations and improvements may be made without departing from the spirit of the present application and these would all fall within the scope of protection of the present application. Therefore, the scope of protection of the present patent application shall be in accordance with the appended claims.

What is claimed is:

1. A display panel, comprising:
a substrate;
a light-emitting functional layer disposed on a side of the substrate, the light-emitting functional layer comprising a light-emitting layer and a first electrode layer disposed in sequence in a direction away from the substrate, and the light-emitting layer comprising a plurality of light-emitting units;
a plurality of touch electrodes spaced apart on a side of the substrate; wherein in the same touch electrode, the touch electrode comprises a plurality of touch electrode portions arranged at intervals in a second direction; and there is a first spacing between two of the touch electrodes disposed adjacent to each other in a first direction; and
a plurality of touch leads, at least part of the touch leads being disposed in a same layer as the touch electrodes, and at least part of the touch leads extending in the second direction and located in the first spacings; and the plurality of touch leads being disposed corresponding to the plurality of touch electrodes, and a touch lead being connected to corresponding ends of the plurality of touch electrode portions of a corresponding touch electrode.

2. The display panel according to claim 1, wherein there is a second spacing between adjacent two of the touch electrode portions;
the first electrode layer comprises a plurality of first electrode portions, the first electrode portions being disposed corresponding to the touch electrodes, and the first electrode portions each comprising a first sub-electrode portion and a plurality of second sub-electrode portions; in the first electrode portion and the corresponding the touch electrode, the second sub-electrode portions are disposed corresponding to the second spacings between the touch electrode, orthographic projections of the second sub-electrode portions on the substrate overlap with orthographic projections of the corresponding second spacings on the substrate, and a first sub-electrode portion are connected to ends of the plurality of second sub-electrode portions away from the corresponding touch leads; and the first sub-electrode portions of at least part of adjacent first electrode portions of the first electrode portions in the second direction are connected.

3. The display panel according to claim 1, wherein each of the touch leads comprises a first sub-touch lead, the first sub-touch lead being in contact with a corresponding one of the touch electrodes;
orthographic projections of the plurality of touch leads on the substrate do not overlap with each other;
the touch lead comprises a second sub-touch lead, the second sub-touch lead extending in a direction away from the corresponding touch electrode in the second direction and being disposed at a distance from the first sub-touch lead;
the touch lead comprises a third sub-touch lead located between the first sub-touch lead and the second sub-touch lead;
in adjacent two of the touch electrodes in the second direction, the two touch electrodes are disposed opposite each other in the second direction; or, in the adjacent two of the touch electrodes in the second direction, the two touch electrodes are disposed partially opposite each other and partially misaligned with each other in the second direction.

4. The display panel according to claim 1, wherein there is a second spacing between adjacent two of the touch electrode portions; the second spacing comprises a plurality of first openings and first gaps, the plurality of first openings being arranged at intervals in the first direction, and adjacent two of the first gaps communicating with each other through the first gap; and
the first openings are disposed corresponding to the light-emitting units, orthographic projections of the light-emitting units on the substrate overlapping with orthographic projections of the corresponding first openings on the substrate.

5. The display panel according to claim 4, wherein at least one of the first openings are disposed corresponding to at least two of the light-emitting units arranged in the second direction.

6. The display panel according to claim 4, wherein in two of the first openings disposed adjacent to each other in the first direction, each of the first openings corresponds to the same number of the light-emitting units, or in the two first openings disposed adjacent to each other in the first direction, each of the first openings corresponds to a different number of the light-emitting units; and
in the two first openings disposed adjacent to each other in the first direction, the number of the light-emitting units corresponding to one of the first openings is 1, and the number of the light-emitting units corresponding to the other of the first openings is 2.

7. The display panel according to claim 4, wherein in the plurality of first gaps between the two adjacent touch electrode portions, adjacent two of the first gaps are misaligned with each other in the first direction;
or in the plurality of first gaps between the two adjacent touch electrode portions, adjacent two of the first gaps are disposed apposite each other in the first direction; and in the plurality of first gaps between the two adjacent touch electrode portions, each of the first gaps is arranged in a straight line.

8. The display panel according to claim 4, wherein orthographic projections of the first gaps on the substrate are first orthographic projections, the orthographic projections of the light-emitting units on the substrate are second orthographic projections, wherein at least part of the second orthographic projections are disposed corresponding to the first orthographic projections, and the second orthographic projections are disposed opposite the corresponding first orthographic projections in the first direction.

9. The display panel according to claim 4, wherein in the same touch electrode portion, the touch electrode portion comprises a plurality of first extension sections and a plurality of first connecting sections, wherein the plurality of first extension sections are arranged at intervals in the first direction, and adjacent two of the first extensions are connected by the first connecting section;
an orthographic projection of each of the first extension sections on the substrate is located at least partially between the orthographic projections of two of the light-emitting units disposed adjacent to each other in the first direction on the substrate; and
an orthographic projection of each of the first connecting sections on the substrate is located at least partially between the orthographic projections of two of the light-emitting units disposed adjacent to each other in the second direction on the substrate.

10. The display panel according to claim 9, wherein adjacent two of the touch electrode portions are defined as a first touch electrode portion and a second touch electrode portion, respectively, the first extension sections of the first touch electrode portion being disposed corresponding to the first extension sections of the second touch electrode portion, the first gaps being provided between the first extension sections of the first touch electrode portion and the first extension sections of the corresponding second touch electrode portion, and the first extension sections of the first touch electrode portion are disposed opposite the first extension sections of the corresponding second touch electrode portion in the second direction; and the first connecting sections of the first touch electrode portion are disposed corresponding to the first connecting sections of the second touch electrode portion, the first openings are provided between the first connecting sections of the first touch electrode portion and the first connecting sections of the corresponding second touch electrode portion, and the first connecting sections of the first touch electrode portion are disposed opposite the first connecting sections of the corresponding second touch electrode portion in the second direction.

11. The display panel according to claim 9, wherein in the same touch electrode portion, the same ends of the first extension sections of at least part of adjacent ones of the first extension sections in the second direction are connected to the first connecting sections; or each of the first extension sections comprises a first extension segment, a second extension segment and a third extension segment arranged in sequence in the second direction; and in the same touch electrode portion, the second extension segments of adjacent two of the first extension sections are each connected to the first connecting sections.

12. The display panel according to claim 1, wherein the display panel comprises a plurality of rows of touch electrodes, wherein each row of touch electrodes comprises a plurality of the touch electrodes arranged in the second direction, and the plurality of rows of touch electrodes are arranged in the first direction;
the display panel comprises a plurality of first dummy electrodes disposed on one side of the substrate, the first dummy electrodes being provided between at least part of adjacent ones of the rows of touch electrodes;
the first dummy electrodes and the touch electrodes are formed in a same layer with a same material; in the same first dummy electrode, the first dummy electrode comprises a plurality of first dummy electrode portions, the plurality of first dummy electrode portions being arranged at intervals in the first direction, with a third spacing between adjacent two of the first dummy electrode portions;
the third spacing comprises a plurality of second openings and second gaps, the plurality of second openings being arranged at intervals in the second direction, and adjacent two of the second gaps communicating with each other through the second gap; the second openings are disposed corresponding to the light-emitting units, and orthographic projections of the light-emitting units on the substrate overlap with orthographic projections of the corresponding second openings on the substrate;
orthographic projections of the first dummy electrodes on the substrate are disposed at a distance from the orthographic projections of the light-emitting units on the substrate; in the row of touch electrodes and the corresponding touch leads, the touch leads are located on a side of the row of touch electrodes in the first direction, and the first dummy electrodes are located on the other side of the row of touch electrodes in the first direction; or the display panel comprises a plurality of touch electrode groups,
wherein each of the touch electrode groups comprises two of the touch electrodes arranged in the first direction, and the touch leads corresponding to the two touch electrodes of the touch electrode group are electrically connected.

13. The display panel according to claim 12, wherein in the same first dummy electrode portion, the first dummy electrode portion comprises a plurality of first sub-portions arranged at intervals in the second direction, and there is a first auxiliary gap between adjacent two of the first sub-portions;
in the same first sub-portion, the first sub-portion comprises a second extension section, the second extension section extending in the second direction;
in the same first sub-portion, the first sub-portion comprises a plurality of second connecting sections connected to the second extension section, and on the same side of the second extension section in the first direction, the plurality of second connecting sections being arranged at intervals in the second direction;
an orthographic projection of the second extension section on the substrate is located at least partially between the orthographic projections of two of the light-emitting units disposed adjacent to each other in the first direction on the substrate; the third spacing comprises a plurality of second openings and second gaps, the plurality of second openings being arranged at intervals in the second direction, and adjacent two of the second gaps communicating with each other through the second gap; and
the second openings are disposed corresponding to the light-emitting units, and the orthographic projections of the light-emitting units on the substrate overlap with orthographic projections of the corresponding second openings on the substrate.

14. The display panel according to claim 1, wherein the display panel comprises a plurality of columns of touch electrodes, wherein each column of touch electrodes comprises a plurality of the touch electrodes arranged in the first direction, and the plurality of columns of touch electrodes are arranged in the second direction;
the display panel comprises second dummy electrodes disposed on one side of the substrate; the number of the columns of touch electrodes is odd, the plurality of columns of touch electrodes comprise adjacent first and second columns of touch electrodes, the first column of touch electrodes are in the middle among all the columns of touch electrodes, and the second dummy electrodes are located between the first and second columns of touch electrodes; or the number of the columns of touch electrodes is even, the plurality of columns of touch electrodes comprise adjacent third and fourth columns of touch electrodes, the third and fourth columns of touch electrodes are in the middle among all the columns of touch electrodes, and the second dummy electrodes are located between the third and fourth columns of touch electrodes;
each of the second dummy electrodes comprises a plurality of second dummy electrode portions, the plurality of second dummy electrode portions being arrange at intervals in the second direction; there is a fourth spacing between adjacent two of the second dummy electrode portions; and the fourth spacing comprises a plurality of third openings and third gaps, the plurality of third openings being arranged at intervals in the first direction, and adjacent two of the third gaps communicating with each other through the third gap.

15. The display panel according to claim 14, wherein in the same second dummy electrode portion, the second dummy electrode portion comprises a plurality of second sub-portions arranged at intervals in the first direction, and there is a second auxiliary gap between adjacent two of the second sub-portions;
in adjacent two of the second dummy electrode portions, the second auxiliary gaps of one of the second dummy electrode portions are disposed opposite the second auxiliary gaps of the other of the second dummy electrode portions in the second direction; and in the same second sub-portion, the second sub-portion comprises a plurality of third extension sections and third connecting sections, the plurality of third extension sections being arranged at intervals in the first direction, and adjacent two of the third extension sections being connected by the third connecting section.

16. The display panel according to claim 1, wherein the display panel comprises a first isolation structure, wherein the touch electrodes are located on a side of the first isolation structure away from the substrate, the first isolation structure encloses a plurality of fourth openings and fourth gaps, adjacent two of the fourth openings in the first direction communicate with each other through the fourth gap, and the first electrode layer comprises first electrode portions, each of the first electrode portions comprising first sub-electrode portions and second sub-electrode portions, and the second sub-electrode portions being located in the fourth openings and the fourth gaps; and
there is a second spacing between adjacent two of the touch electrode portions, the second spacing comprises first openings and first gaps, the fourth openings are disposed corresponding to the first openings, orthographic projections of the fourth openings on the substrate overlap with orthographic projections of the corresponding first openings on the substrate, the fourth gaps are disposed corresponding to the first gaps, and orthographic projections of the fourth gaps on the substrate overlap with orthographic projections of the corresponding first gaps on the substrate.

17. The display panel according to claim 16, wherein the display panel comprises first dummy electrodes and a second isolation structure, the first electrode layer comprises second electrode portions, the second isolation structure is located between the substrate and the first dummy electrodes, and the first dummy electrodes enclose third spacings and first auxiliary gaps in communication with each other; the second isolation structure encloses fifth spacings and third auxiliary gaps in communication with each other, the second electrode portions are located in the fifth spacings and the third auxiliary gaps, the third spacings are disposed corresponding to the fifth spacings, orthographic projections of the third spacings on the substrate overlap with orthographic projections of the corresponding fifth spacings on the substrate, the first auxiliary gaps are disposed corresponding to the third auxiliary gaps, and orthographic projections of the first auxiliary gaps on the substrate overlap with orthographic projections of the corresponding third auxiliary gaps on the substrate; each of the third spacings comprises a plurality of second openings and second gaps, the plurality of second openings being arranged at intervals in the second direction, and adjacent two of the second openings communicate with each other through the second gap, and each of the fifth spacing comprises a plurality of fifth openings and fifth gaps, the plurality of fifth openings being arranged at intervals in the second direction, and adjacent two of the fifth openings communicating with each other through the fifth gap; and the fifth openings are disposed corresponding to the second openings, orthographic projections of the fifth openings on the substrate overlap with orthographic projections of the corresponding second openings on the substrate, the fifth gaps are disposed corresponding to the second gaps, and orthographic projections of the fifth gaps on the substrate overlap with orthographic projections of the corresponding second gaps on the substrate.

18. The display panel according to claim 17, wherein the display panel comprises second dummy electrodes and a third isolation structure, the first electrode layer comprises third electrode portions, and the third isolation structure is located between the substrate and the second dummy electrodes; the second dummy electrodes enclose fourth spacings and second auxiliary gaps in communication with each other; the third isolation structure encloses sixth spacings and fourth auxiliary gaps in communication with each other, the third electrode portions being located in the sixth spacings and the fourth auxiliary gaps; the fourth spacings are disposed corresponding to the sixth spacings, orthographic projections of the fourth spacings on the substrate overlap with orthographic projections of the corresponding sixth spacings on the substrate, the second auxiliary gaps are disposed corresponding to the fourth auxiliary gaps, and orthographic projections of the second auxiliary gaps on the substrate overlap with orthographic projections of the corresponding fourth auxiliary gaps on the substrate; each of the fourth spacings comprises a plurality of third openings and third gaps, the plurality of third openings being arranged at intervals in the first direction, and adjacent two of the third openings communicating with each other through the third gap; each of the sixth spacings comprises a plurality of sixth openings and sixth gaps, the plurality of sixth openings being arranged at intervals in the first direction, adjacent two of the sixth openings communicating with each other through the sixth gap, and the third electrode portions being located in the sixth openings and the sixth gaps; and the sixth openings are disposed corresponding to the third openings, orthographic projections of the sixth openings on the substrate overlap with orthographic projections of the corresponding third openings on the substrate, the sixth gaps are disposed corresponding to the third gaps, and orthographic projections of the sixth gaps on the substrate overlap with orthographic projections of the corresponding third gaps on the substrate.

19. A display panel, comprising:
a substrate;
a light-emitting functional layer disposed on a side of the substrate, the light-emitting functional layer comprising a light-emitting layer and a first electrode layer disposed in sequence in a direction away from the substrate, and the light-emitting layer comprising a plurality of light-emitting units;
a plurality of touch electrodes spaced apart on a side of the substrate; wherein in the same touch electrode, the touch electrode comprises a plurality of touch electrode portions arranged at intervals in a second direction, there is a first spacing between two of the touch electrodes disposed adjacent to each other in a first direction, and there is a second spacing between adjacent two of the touch electrode portions; and
a plurality of touch leads, at least part of the touch leads being disposed in a same layer as the touch electrodes, at least part of the touch leads extending in the second direction and located in the first spacings; the plurality of touch leads being disposed corresponding to the plurality of touch electrodes, and the touch lead being connected to corresponding ends of the plurality of touch electrode portions of the corresponding touch electrode;
wherein the first electrode layer comprises a plurality of first electrode portions arranged at intervals, the first electrode portions being disposed corresponding to the touch electrodes, and the first electrode portions each comprising first sub-electrode portions and a plurality of second sub-electrode portions; and in the first electrode portions and the corresponding touch electrodes, the second sub-electrode portions are disposed corresponding to the second spacings between the touch electrodes, orthographic projections of the second sub-electrode portions on the substrate overlap with orthographic projections of the corresponding second spacings on the substrate, and the first sub-electrode portions are connected to ends of the plurality of second sub-electrode portions away from the corresponding touch leads.

20. A display device, comprising:
a display panel, comprising:
a substrate;
a light-emitting functional layer disposed on a side of the substrate, the light-emitting functional layer comprising a light-emitting layer and a first electrode layer disposed in sequence in a direction away from the substrate, and the light-emitting layer comprising a plurality of light-emitting units;
a plurality of touch electrodes spaced apart on a side of the substrate; wherein in the same touch electrode, the touch electrode comprises a plurality of touch electrode portions arranged at intervals in a second direction; and there is a first spacing between two of the touch electrodes disposed adjacent to each other in a first direction; and
a plurality of touch leads, at least part of the touch leads being disposed in a same layer as the touch electrodes, and at least part of the touch leads extending in the second direction and located in the first spacings; and the plurality of touch leads being disposed corresponding to the plurality of touch electrodes, and a touch lead being connected to corresponding ends of the plurality of touch electrode portions of a corresponding touch electrode.
